(19) United States
(12) Patent Application Publication
(10) Pub. No.: US 2025/0017020 A1
(43) Pub. Date: Jan. 9, 2025

(54) SEMICONDUCTOR MEMORY DEVICE

(71) Applicant: Kioxia Corporation, Tokyo (JP)

(72) Inventors: Yoko YOSHIMURA, Yokkaichi Mie (JP); Kiwamu Sakuma, Yokkaichi Mie (JP); Kunifumi SUZUKI, Yokkaichi Mie (JP); Hidesato ISHIDA, Yokkaichi Mie (JP)

(73) Assignee: Kioxia Corporation, Tokyo (JP)

(21) Appl. No.: 18/762,786

(22) Filed: Jul. 3, 2024

(30) Foreign Application Priority Data
Jul. 7, 2023 (JP) 2023-112458

(51) Int. Cl. H10B 51/20; H01L 21/28; H01L 23/528; H01L 23/532; H01L 29/51

(52) U.S. Cl. CPC H10B 51/20; H01L 29/40111; H01L 29/516

(57) ABSTRACT

A semiconductor memory device includes a semiconductor layer; a gate electrode; a first insulating film provided between the semiconductor layer and the gate electrode, and including at least one of oxygen, hafnium, or a first additive element; and a second insulating film provided between the first insulating film and the gate electrode. The first insulating film includes a first additive region, a second additive region provided between the first additive region and the gate electrode, and a memory region provided between the first additive region and the second additive region. The first additive region includes a second additive element selected from a group consisting of ruthenium, titanium, molybdenum, tantalum, tungsten, platinum, and combinations thereof. The second additive region includes a third additive element selected group consisting of ruthenium, titanium, molybdenum, tantalum, tungsten, platinum, and combinations thereof.

### CROSS-REFERENCE TO RELATED APPLICATION

This application is based upon and claims the benefit of priority from Japanese Patent Application No. 2023-112458, filed Jul. 7, 2023, the entire contents of which are incorporated herein by reference.

### FIELD

Embodiments described herein relate generally to a semiconductor memory device.

### BACKGROUND

Semiconductor memory devices including a plurality of memory transistors are known. Each of gate insulating films of the plurality of memory transistors is provided with a memory unit that can store data, for example, an insulating charge storage layer such as silicon nitride (Si₃N₄), a conductive charge storage layer such as a floating gate, a ferroelectric film, or the like.

### DESCRIPTION OF THE DRAWINGS

FIG. 1 is a schematic circuit diagram showing a partial configuration of a memory die MD according to a first embodiment;

FIG. 2 is a schematic plan view of the memory die MD;

FIG. 3 is a schematic perspective view showing a partial configuration of the memory die MD;

FIG. 4 is a schematic cross-sectional view showing an enlarged part of FIG. 3;

FIG. 5 is a schematic histogram illustrating a threshold voltage of a memory cell MC;

FIG. 6 is a schematic graph illustrating a polarizability of the memory cell MC;

FIG. 7 is a schematic cross-sectional view illustrating the state of the memory cell MC;

FIG. 8 is a schematic energy band diagram illustrating the state of the memory cell MC;

FIG. 9 is a schematic cross-sectional view illustrating the state of the memory cell MC;

FIG. 10 is a schematic energy band diagram illustrating the state of the memory cell MC;

FIG. 11 is a schematic energy band diagram illustrating the effects of the first embodiment;

FIG. 12 is a schematic energy band diagram illustrating the effects of the first embodiment;

FIG. 13 is a schematic cross-sectional view illustrating a manufacturing method of the memory die MD;

FIG. 14 is a schematic cross-sectional view illustrating the manufacturing method;

FIG. 15 is a schematic cross-sectional view illustrating the manufacturing method;

FIG. 16 is a schematic cross-sectional view showing a partial configuration of a semiconductor memory device according to a second embodiment;

FIG. 17 is a schematic cross-sectional view illustrating a manufacturing method of the semiconductor memory device;

FIG. 18 is a schematic cross-sectional view showing a partial configuration of a semiconductor memory device according to a third embodiment;

FIG. 19 is a schematic cross-sectional view illustrating a manufacturing method of the semiconductor memory device;

FIG. 20 is a schematic cross-sectional view illustrating the manufacturing method.

FIG. 21 is a schematic cross-sectional view illustrating the manufacturing method.

FIG. 22 is a schematic cross-sectional view illustrating the manufacturing method.

FIG. 23 is a schematic cross-sectional view illustrating the manufacturing method.

FIG. 24 is a schematic cross-sectional view showing a partial configuration of a semiconductor memory device according to a fourth embodiment.

FIG. 25 is a schematic cross-sectional view illustrating a manufacturing method of the semiconductor memory device;

FIG. 26 is a schematic cross-sectional view illustrating the manufacturing method;

FIG. 27 is a schematic cross-sectional view illustrating the manufacturing method;

FIG. 28 is a schematic cross-sectional view illustrating the manufacturing method;

FIG. 29 is a schematic cross-sectional view illustrating the manufacturing method;

FIG. 30 is a schematic cross-sectional view showing a partial configuration of a semiconductor memory device according to a fifth embodiment;

FIG. 31 is a schematic cross-sectional view illustrating a manufacturing method of the semiconductor memory device;

FIG. 32 is a schematic cross-sectional view illustrating the manufacturing method;

FIG. 33 is a schematic cross-sectional view illustrating the manufacturing method;

FIG. 34 is a schematic cross-sectional view showing a partial configuration of a semiconductor memory device according to a sixth embodiment;

FIG. 35 is a schematic cross-sectional view illustrating a manufacturing method of the semiconductor memory device;

FIG. 36 is a schematic cross-sectional view illustrating the manufacturing method;

FIG. 37 is a schematic cross-sectional view illustrating the manufacturing method;

FIG. 38 is a schematic cross-sectional view illustrating the manufacturing method;

FIG. 39 is a schematic cross-sectional view illustrating the manufacturing method;

FIG. 40 is a schematic cross-sectional view showing a partial configuration of a semiconductor memory device according to a seventh embodiment;

FIG. 41 is a schematic cross-sectional view illustrating a manufacturing method of the semiconductor memory device according to the seventh embodiment;

FIG. 42 is a schematic cross-sectional view illustrating the manufacturing method; and

FIG. 43 is a schematic cross-sectional view illustrating the manufacturing method.

### DETAILED DESCRIPTION

Embodiments provide a semiconductor memory device that operates suitably.

In general, according to one embodiment, a semiconductor memory device includes a semiconductor layer; a gate electrode facing the semiconductor layer; a first insulating film provided between the semiconductor layer and the gate electrode, and including at least one of oxygen (O), hafnium (Hf), or a first additive element, the first insulating film formed with an orthorhombic crystal structure; and a second insulating film provided between the first insulating film and the gate electrode. The first insulating film includes a first additive region, a second additive region provided between the first additive region and the gate electrode, and a memory region provided between the first additive region and the second additive region. The first additive region includes a second additive element selected from a group consisting of ruthenium (Ru), titanium (Ti), molybdenum (Mo), tantalum (Ta), tungsten (W), platinum (Pt), and combinations thereof. The second additive region includes a third additive element selected from a group consisting of ruthenium (Ru), titanium (Ti), molybdenum (Mo), tantalum (Ta), tungsten (W), platinum (Pt), and combinations thereof. The memory region does not include the second additive element, or a concentration of the second additive element in the memory region is lower than a concentration of the second additive element in the first additive region. The memory region does not include the third additive element, or a concentration of the third additive element in the memory region is lower than a concentration of the third additive element in the second additive region.

Next, semiconductor memory devices according to embodiments will be described in detail with reference to the drawings. The following embodiments are merely examples, and are not intended to limit the disclosure. The following drawings are schematic, and some configurations may be omitted for convenience of explanation. Parts common to plurality of embodiments are given the same reference numerals, and description thereof may be omitted.

In the present specification, “semiconductor memory device” may mean a memory die, or may mean a memory system that includes a controller die such as a memory chip, a memory card, or a solid state drive (SSD). The word can also mean a configuration that includes a host computer such as a smartphone, a tablet terminal, or a personal computer.

In the present specification, “control circuit” may mean a peripheral circuit such as a sequencer provided on a memory die, or may mean a controller die or a controller chip connected to a memory die, or may mean a configuration that includes both.

In the present specification, when it is said that a first configuration is “electrically connected” to a second configuration, the expression may mean that the first configuration is directly connected to the second configuration, or that the first configuration is connected to the second configuration via wiring, a semiconductor member, a transistor, or the like. For example, when three transistors are connected in series, the first transistor is “electrically connected” to the third transistor even if the second transistor enters an OFF state.

In the present specification, when it is said that the first configuration is “connected between” the second configuration and the third configuration, the expression may mean that the first configuration, the second configuration, and the third configuration are connected in series and the second configuration is connected to the third configuration via the first configuration.

In the present specification, when it is said that two wirings or the like “are electrically connected” by a circuit or the like, the expression may mean that the circuit or the like includes a transistor or the like, the transistor or the like is provided in a current path between the two wirings, and the transistor or the like enters ON state.

In the present specification, a predetermined direction parallel to an upper surface of a substrate is referred to as an X direction, a direction parallel to the upper surface of the substrate and perpendicular to the X direction is referred to as a Y direction, and a direction perpendicular to the upper surface of the substrate is referred to as a Z direction.

In the present specification, the direction intersecting the upper surface of the substrate may be referred to as a stacking direction. The stacking direction may or may not match the Z direction. In the present specification, a direction along a predetermined plane intersecting the stacking direction may be referred to as a first direction, and a direction intersecting the first direction along the predetermined plane may be referred to as a second direction. The first direction and the second direction may or may not correspond to either the X direction or the Y direction.

In the present specification, expressions such as “above” and “below” are based on the substrate. For example, a direction away from the substrate along the Z direction is referred to as upward, and a direction toward the substrate along the Z direction is referred to as downward. A lower surface or a lower end of a certain configuration mean a surface or an end of the certain configuration on the substrate side, and an upper surface or an upper end mean a surface or an end of the certain configuration on the opposite side of the substrate. A surface that intersects with the X direction or the Y direction is referred to as a side surface or the like.

In the present specification, when referring to “width”, “length”, or “thickness” of a configuration, a member, or the like, the expression may mean the width, length, thickness, or the like in a cross section observed by scanning electron microscopy (SEM), transmission electron microscopy (TEM), or the like.

### First Embodiment

### [Circuit Configuration of Memory Die MD]

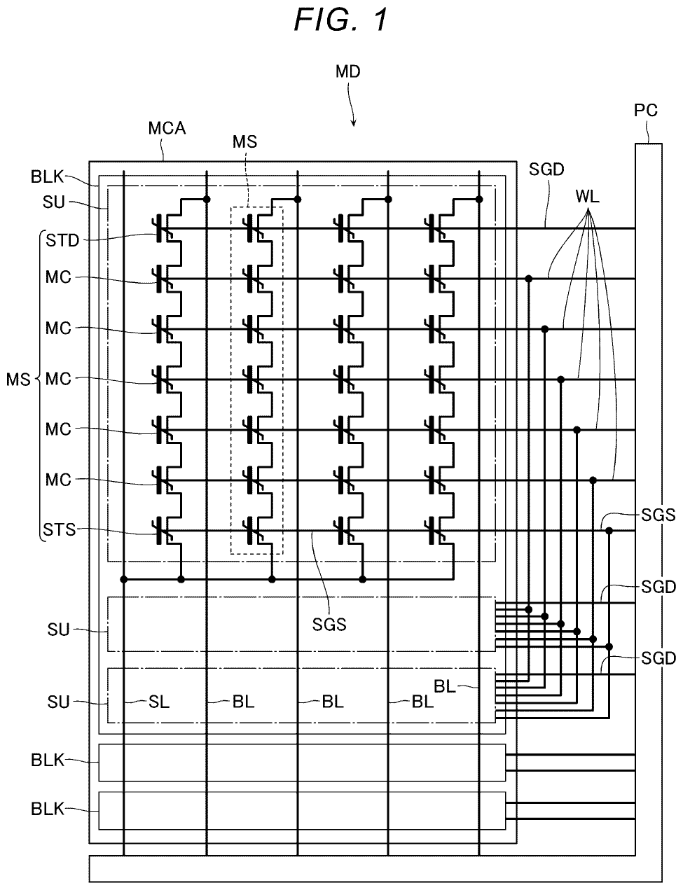

FIG. 1 is a schematic circuit diagram showing a partial configuration of a memory die MD according to a first embodiment. As shown in FIG. 1, the memory die MD includes a memory cell array MCA that stores data, and a peripheral circuit PC connected to the memory cell array MCA.

The memory cell array MCA includes a plurality of memory blocks BLK, as shown in FIG. 1. Each of the memory blocks BLK includes a plurality of string units SU. Each of the string units SU includes a plurality of memory strings MS. One end of each of the plurality of memory strings MS is connected to the peripheral circuit PC via a plurality of electrically independent bit lines BL. The other end of each of the plurality of memory strings MS is connected to the peripheral circuit PC via one electrically common source line SL.

The memory string MS includes a drain-side select transistor STD, a plurality of memory cells MC (memory transistors), and a source-side select transistor STS, which are connected in series between the bit line BL and the source line SL. Hereinafter, the drain-side select transistor STD and the source-side select transistor STS may be simply referred to as select transistors (STD, STS).

The memory cell MC is an electric field effect transistor including a semiconductor layer functioning as a channel region, a gate insulating film including a memory unit, and a gate electrode. A threshold voltage of the memory cell MC changes depending on the state of the memory unit. The memory cell MC stores one bit or plurality of bits of data. The gate electrodes of the plurality of memory cells MC corresponding to one memory string MS are connected to word lines WL, respectively. The word lines WL are each commonly connected to all memory strings MS in one memory block BLK.

The select transistors (STD, STS) are an electric field effect transistor that includes a semiconductor layer functioning as a channel region, a gate insulating film, and a gate electrode. Select gate lines (SGD, SGS) are connected to the gate electrodes of the select transistors (STD, STS), respectively. A drain-side select gate line SGD is provided corresponding to the string unit SU, and is commonly connected to all the memory strings MS in one string unit SU. A source-side select gate line SGS is commonly connected to all memory strings MS in the memory block BLK.

The peripheral circuit PC includes, for example, a voltage generation circuit that generates an operating voltage and outputs the operating voltage to a voltage supply line, a decoding circuit that electrically connects a desired voltage supply line to the bit line BL, the source line SL, the word line WL, and the select gate lines (SGD, SGS), a sense amplifier circuit that detects current or voltage of the bit line BL, a sequencer that controls the circuits, and the like.

### [Structure of Memory Die MD]

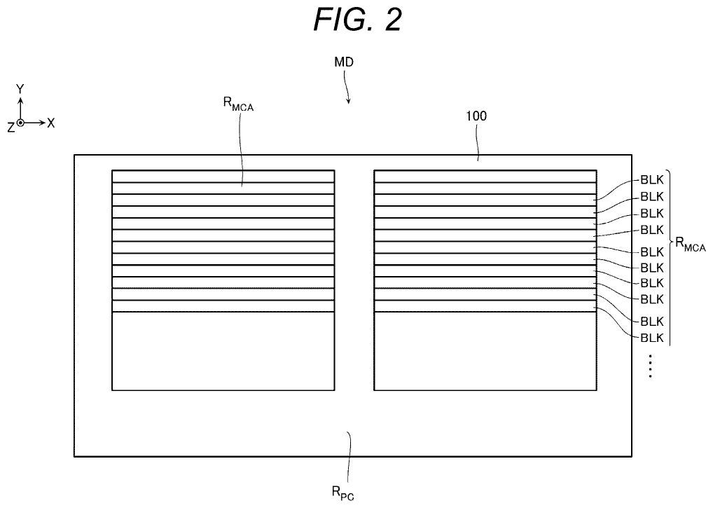

FIG. 2 is a schematic plan view of the memory die MD. As shown in FIG. 2, the memory die MD includes a semiconductor substrate 100. In the illustrated example, the semiconductor substrate 100 is provided with two memory cell array regions R_{MCA} arranged in the X direction. A plurality of memory blocks BLK arranged in the Y direction are provided in the memory cell array region R_{MCA}. A peripheral circuit region R_{PC} is provided at an end of the semiconductor substrate 100 in the Y direction.

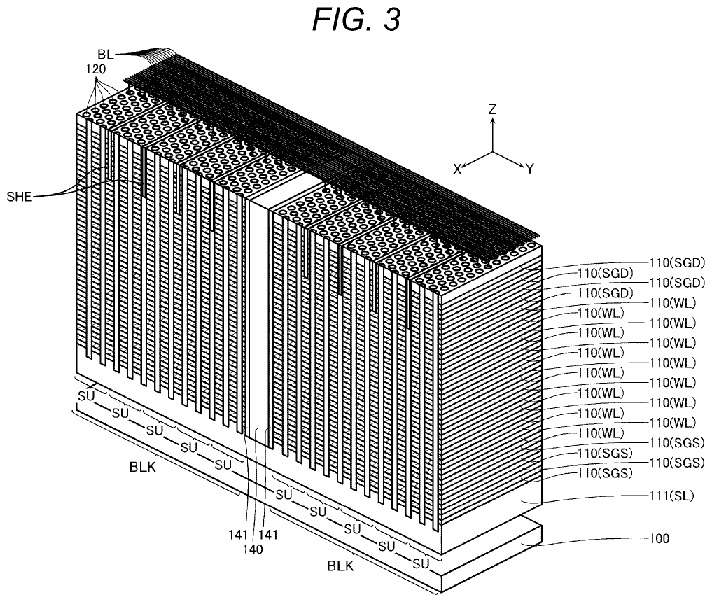

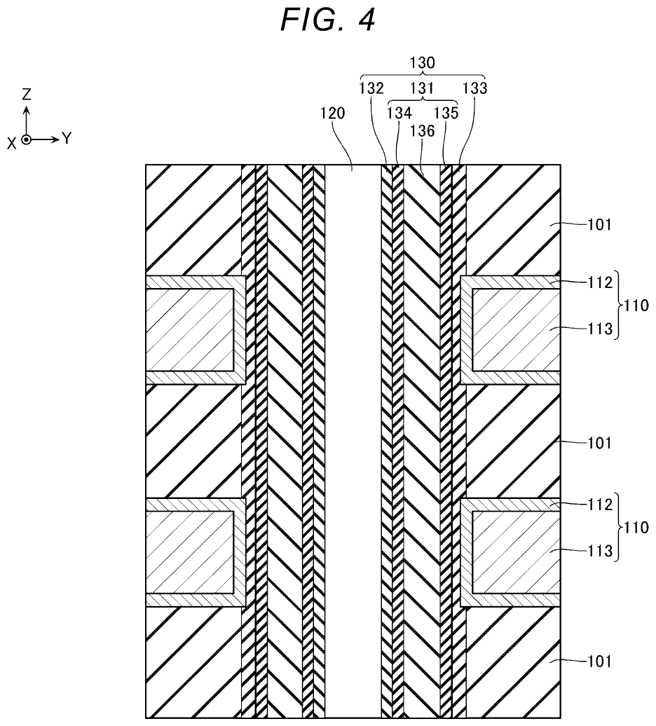

FIG. 3 is a schematic perspective view showing a partial configuration of the memory die MD. FIG. 4 is a schematic cross-sectional view showing an enlarged part of FIG. 3.

As shown in FIG. 3, the memory block BLK includes a plurality of conductive layers 110 arranged in the Z direction above the semiconductor substrate 100, a conductive layer 111 provided below the plurality of conductive layers 110 (between the plurality of conductive layers 110 and the semiconductor substrate 100), and a plurality of semiconductor layers 120 extending in the Z direction. As shown in FIG. 4, the memory block BLK includes a plurality of gate insulating films 130 provided between the plurality of conductive layers 110 and the plurality of semiconductor layers 120, respectively. As shown in FIG. 3, the memory block BLK includes an electrode 140 connected to the conductive layer 111. The bit line BL described with reference to FIG. 1 is provided above such configurations.

The semiconductor substrate 100 is made of, for example, P-type silicon (Si) including P-type impurities such as boron (B). A surface of the semiconductor substrate 100 is provided with, for example, an N-type well region including an N-type impurity such as phosphorus (P), a P-type well region including a P-type impurity such as boron (B), and a semiconductor substrate region in which the N-type well region and the P-type well region are not provided. The N-type well region, the P-type well region, and the semiconductor substrate region each function as part of a plurality of transistors, a plurality of capacitors, or the like that configure the peripheral circuit PC.

The conductive layer 110 is a substantially plate-shaped conductive layer extending in the X direction. The conductive layer 110 may include a stacked film or the like of a barrier conductive film 112 of titanium nitride (TiN) or the like and a metal film 113 of tungsten (W) or the like, for example, as illustrated in FIG. 4. The conductive layer 110 may include, for example, polycrystalline silicon including impurities such as phosphorus (P) or boron (B). An insulating layer 101 made of silicon oxide (SiO₂) or the like is provided between the plurality of conductive layers 110 arranged in the Z direction.

The plurality of conductive layers 110 function as the word line WL described with reference to FIG. 1 and the gate electrodes of the plurality of memory cells MC connected to the word line WL. In the following description, such a conductive layer 110 may be referred to as a conductive layer 110 (WL). The plurality of conductive layers 110 (WL) are each electrically independent for each memory block BLK. When focusing on two memory blocks BLK adjacent in the Y direction, in the two memory blocks BLK, a plurality of conductive layers 110 (WL) arranged in the Z direction and a plurality of insulating layers 101 provided on the upper and lower surfaces of the plurality of conductive layers 110 (WL) are divided in the Y direction.

One or a plurality of conductive layers 110 located below the plurality of conductive layers 110 (WL) function as the gate electrodes of the source-side select gate line SGS and the plurality of source-side select transistors STS connected to the source-side select gate line SGS described with reference to FIG. 1. In the following description, such a conductive layer 110 may be referred to as a conductive layer 110 (SGS). When focusing on two memory blocks BLK adjacent in the Y direction, in the two memory blocks BLK, one or a plurality of conductive layers 110 (SGS) and a plurality of insulating layers 101 provided on the upper and lower surfaces of the one or plurality of conductive layers 110 (SGS) are divided in the Y direction.

One or a plurality of conductive layers 110 located above the plurality of conductive layers 110 (WL) function as the gate electrodes of the drain-side select gate line SGD and the plurality of drain-side select transistors STS connected to the drain-side select gate line SGD described with reference to FIG. 1. In the following description, such a conductive layer 110 may be referred to as a conductive layer 110 (SGD).

As shown in FIG. 3, the width of the plurality of conductive layers 110 (SGD) in the Y direction is smaller than the width of the conductive layer 110 (WL) in the Y direction.

The plurality of conductive layers 110 (SGD) are electrically independent for each string unit SU. When focusing on two string units SU adjacent in the Y direction in each memory block BLK, in the two string units SU, one or a plurality of conductive layers 110 (SGD) are divided in the Y direction via an inter-string unit insulating member SHE. When focusing on a string unit SU which is closest to the other memory block among the plurality of string units SU included in one of two memory blocks BLK adjacent to each other in the Y direction, and a string unit SU which is closest to the one memory block among the plurality of string units SU included in the other memory block, in the two string units SU, a plurality of conductive layers 110 (SGD) are divided in the Y direction.

The conductive layer 111 may include, for example, polycrystalline silicon including an N-type impurity such as phosphorus (P). Metal such as tungsten (W), a conductive member such as tungsten silicide, or another conductive member may be provided on the lower surface of the conductive layer 111. The conductive layer 111 functions as a part of the source line SL described with reference to FIG. 1.

The semiconductor layers 120 are arranged in a predetermined pattern in the X direction and the Y direction. The semiconductor layer 120 functions as a channel region of a plurality of memory cells MC and select transistors STD and STS included in one memory string MS (FIG. 1). The semiconductor layer 120 is, for example, a semiconductor layer of polycrystalline silicon (Si) or the like. The semiconductor layer 120 has a substantially columnar shape. The outer peripheral surfaces of the semiconductor layers 120 are each surrounded by the conductive layer 110 and are facing the conductive layer 110.

An impurity region including an N-type impurity such as phosphorus (P) (not shown) is provided at the upper end of the semiconductor layer 120. The impurity region is electrically connected to the bit line BL via a via contact electrode (not shown).

An impurity region including an N-type impurity such as phosphorus (P) (not shown) is provided at the lower end of the semiconductor layer 120. The impurity region is connected to the conductive layer 111.

The gate insulating film 130 (FIG. 4) has a substantially columnar shape extending in the Z direction over a range in the Z direction corresponding to the plurality of conductive layers 110 along the outer peripheral surface of the semiconductor layer 120. The gate insulating film 130 includes a substantially cylindrical ferroelectric film 131 extending in the Z direction over a range in the Z direction corresponding to the plurality of conductive layers 110 along the outer peripheral surface of the semiconductor layer 120, a substantially cylindrical insulating film 132 (boundary layer) extending in the Z direction over a range in the Z direction corresponding to the plurality of conductive layers 110 along the inner peripheral surface of the ferroelectric film 131, and a substantially cylindrical insulating 133 (boundary film layer) extending in the Z direction over a range in the Z direction corresponding to the plurality of conductive layers 110 along the outer peripheral surface of the ferroelectric film 131.

The ferroelectric film 131 may be, for example, an insulating film including orthorhombic hafnium oxide. The hafnium oxide included in the ferroelectric film 131 may be mainly orthorhombic. More specifically, the hafnium oxide included in the ferroelectric film 131 may be mainly a third orthorhombic crystal (orthorhombic III, space group Pbc21, space group number 29). Among the hafnium oxide crystals included in the ferroelectric film 131, orthorhombic crystals may occupy the largest proportion. The crystal structure in the ferroelectric film 131 can be observed by, for example, a method such automated crystal orientation mapping as transmission electron microscopy (ACOM-TEM).

The ferroelectric film 131 can include at least one additive element selected from the group including silicon (Si), zirconium (Zr), aluminum (Al), yttrium (Y), strontium (Sr), lanthanum (La), samarium (Sm), gadolinium (Gd), terbium (Tb), dysprosium (Dy), holmium (Ho), erbium (Er), ytterbium (Yb), lutetium (Lu), and barium (Ba). Hereinafter, such an additive element may be referred to as a “first additive element”. The presence and concentration of the additive element can be confirmed, for example, by a method such as energy dispersive X-ray spectroscopy (EDX).

From the viewpoint of causing hafnium oxide exhibit ferroelectricity, the concentration of the first additive element is preferably set to 0.1 atom % or more and 80 atom % or less. The appropriate range of the concentration of the first additive element for causing hafnium oxide to exhibit ferroelectricity varies depending on the type of the first additive element. For example, when the first additive element is silicon (Si), the appropriate range of the concentration of the first additive element to exhibit ferroelectricity is 3 atom % or more and 7 atom % or less. For example, when the first additive element is barium (Ba), the appropriate range of the concentration of the first additive element to exhibit ferroelectricity is 0.1 atom % or more and 3 atom % or less. For example, when the first additive element is zirconium (Zr), the appropriate range of the concentration of the first additive element to exhibit ferroelectricity is 10 atom % or more and 80 atom % or less.

The ferroelectric film 131 includes an additive region 134 that includes the inner peripheral surface of the ferroelectric film 131 (the surface on the semiconductor layer 120 side), an additive region 135 that includes the outer peripheral surface of the ferroelectric film 131 (the surface on the conductive layer 110 side), and a memory region 136 provided between the additive region 134 and the additive region 135.

The additive region 134 includes at least one additive element selected from a group including ruthenium (Ru), titanium (Ti), molybdenum (Mo), tantalum (Ta), tungsten (W), and platinum (Pt), in addition to the first additive element described above. Hereinafter, such an additive element may be referred to as a “second additive element”. The concentration of the second additive element in the additive region 134 may be, for example, 6.2×10²¹ pieces/cm³ or less.

The additive region 135 includes at least one additive element selected from a group including ruthenium (Ru), titanium (Ti), molybdenum (Mo), tantalum (Ta), tungsten (W), and platinum (Pt), in addition to the first additive element described above. Hereinafter, such an additive element may be referred to as a “third additive element”. The concentration of the third additive element in the additive region 135 may be, for example, 6.2×10²¹ pieces/cm³ or less. The type and concentration of the third additive element in the additive region 135 may be the same as or different from the type and concentration of the second additive element in the additive region 134.

The memory region 136 may or may not include the second additive element, in addition to the first additive element described above. When the memory region 136 includes the second additive element, the concentration of the second additive element in the memory region 136 is lower than the concentration of the second additive element in the additive region 134. When the memory region 136 includes the second additive element, a boundary between the memory region 136 and the additive region 134 may be, for example, a position where the concentration of the second additive element is half of a peak value. When the memory region 136 does not include the second additive element, a boundary between the memory region 136 and the additive region 134 may be, for example, a boundary between a region including the second additive element and a region not including the second additive element, or may be a boundary between a region where the second additive element can be detected and a region where the second additive element cannot be detected.

The memory region 136 may or may not include the third additive element, in addition to the first additive element described above. When the memory region 136 includes the third additive element, the concentration of the third additive element in the memory region 136 is lower than the concentration of the third additive element in the additive region 135. When the memory region 136 includes the third additive element, a boundary between the memory region 136 and the additive region 135 may be, for example, a position where the concentration of the third additive element is half of a peak value. When the memory region 136 does not include the third additive element, a boundary between the memory region 136 and the additive region 135 may be, for example, a boundary between a region including the third additive element and a region not including the third additive element, or may be a boundary between a region where the third additive element can be detected and a region where the third additive element cannot be detected.

The thickness (radial length) of the memory region 136 is greater than the thickness (radial length) of the additive region 134 and the thickness (radial length) of the additive region 135. The thickness of the memory region 136 may be, for example, 8 nm or more. Here, when the thickness of the memory region 136 is 8 nm or more, the memory region 136 tends to exhibit ferroelectricity, and when the thickness is less than 8 nm, the memory region 136 tends not to exhibit ferroelectricity. In particular, when the thickness of the memory region 136 is 5 nm or less, the memory region 136 tends not to exhibit ferroelectricity.

The thickness (radial length) of the memory region 136 can be defined by various methods. For example, in the present embodiment, the distance between the additive region 134 and the additive region 135 may be the thickness of the memory region 136.

The insulating film 132 is provided between the ferroelectric film 131 and the semiconductor layer 120 extending in the Z direction. In the illustrated example, the insulating film 132 is in contact with the ferroelectric film 131 and the semiconductor layer 120. The insulating film 132 includes, for example, silicon oxynitride (SiON).

The insulating 133 film is provided between the ferroelectric film 131 and the plurality of conductive layers 110 arranged in the Z direction. In the illustrated example, the insulating film 133 is in contact with the ferroelectric film 131 and the plurality of conductive layers 110 arranged in the Z direction. The insulating film 133 includes, for example, silicon oxide (SiO₂), silicon oxynitride (SiON), or the like.

The electrode 140 extends in the X direction and the Z direction, as shown in FIG. 3, for example. An insulating film 141 made of silicon oxide (SiO₂) or the like is provided on both side surfaces of the electrode 140 in the Y direction. The electrode 140 is spaced apart in the Y direction from the plurality of conductive layers 110 arranged in the Z direction and the plurality of insulating layers 101 provided between the conductive layers 110, via the insulating films 141. The lower ends of the electrode 140 and the insulating film 141 are connected to the conductive layer 111. The electrode 140 may be a conductive member including, for example, a stacked film or the like of a barrier conductive film of titanium nitride (TiN) or the like and a metal film of tungsten (W) or the like. The electrode 140 may be, for example, a semiconductor member such as polycrystalline silicon including impurities such as phosphorus (P) or boron (B). The electrode 140 functions as a part of the source line SL described with reference to FIG. 1.

### [Threshold Voltage of Memory Cell MC]

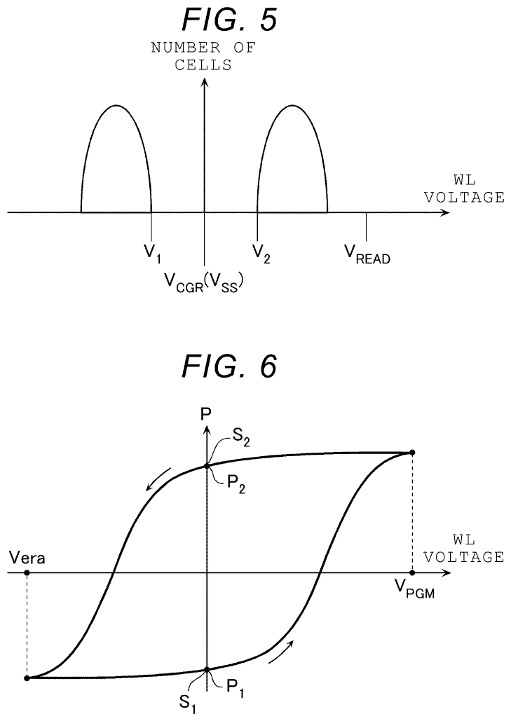

Next, with reference to FIG. 5, the threshold voltage of the memory cell MC will be described. FIG. 5 is a schematic histogram illustrating the threshold voltage of the memory cell MC. The horizontal axis shows the voltage of the word line WL, and the vertical axis shows the number of memory cells MC. The threshold voltage referred to here is a threshold voltage when the memory cell MC is operated as an NMOS transistor.

In the example of FIG. 5, the threshold voltage of the memory cell MC is controlled to two states. For example, the threshold voltage of the memory cell MC controlled to the lower state is negative, and the absolute value of the lower state threshold voltage is greater than the absolute value of a negative polarity voltage V₁ in FIG. 5. The threshold voltage of the memory cell MC controlled to the higher state is positive, and the absolute value of the higher state threshold voltage is greater than the absolute value of a positive polarity voltage V₂ in FIG. 5.

In a read operation, for example, a read voltage V_{CGR} between the negative polarity voltage V₁ and the positive polarity voltage V₂ is supplied to the selected word line WL. In the example of FIG. 5, the read voltage V_{CGR} has a magnitude approximately equal to a ground voltage V_{SS}. Thus, an electron channel is formed in the channel region of the selected memory cell MC controlled to the lower state, and no channel is formed in the channel region of the selected memory cell MC controlled to the higher state.

In the read operation, for example, a read pass voltage V_{READ} higher than the threshold voltage of the memory cell MC controlled to the higher state is supplied to the non-selected word line WL. Thus, the non-selected memory cells MC are turned on regardless of the data to be recorded. Thus, the selected memory cell MC is electrically connected to the bit line BL (FIG. 1) and the source line SL (FIG. 1). Therefore, by supplying a voltage between the bit line BL and the source line SL here and detecting whether current flows through the bit line BL, it is possible to read the data recorded in the selected memory cell MC.

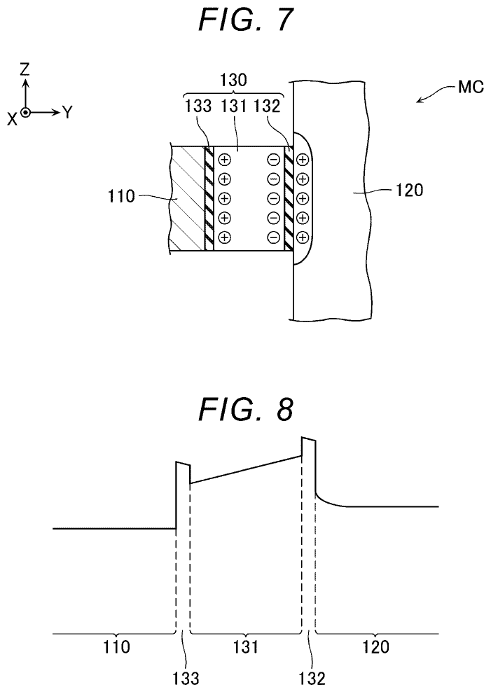

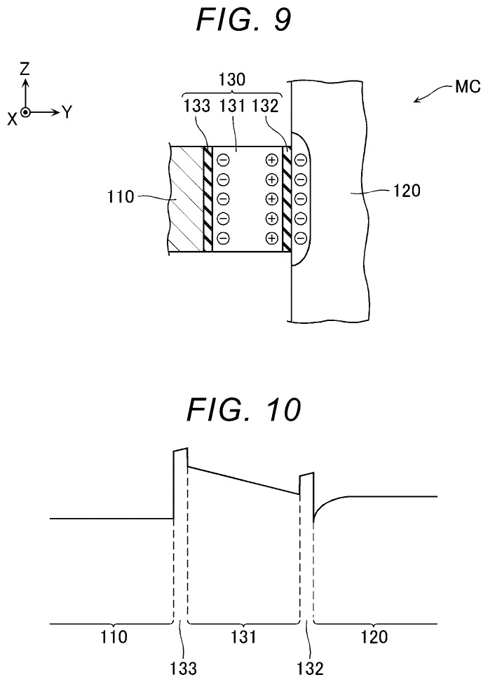

Next, a method for controlling the threshold voltage of the memory cell MC will be described with reference to FIGS. 6 to 10. FIG. 6 is a schematic graph illustrating a polarizability of the memory cell MC. The horizontal axis of the graph shown in FIG. 6 indicates the voltage of the word line WL. The vertical axis of the graph shown in FIG. 6 indicates a polarizability P of the ferroelectric film 131. FIG. 7 is a schematic cross-sectional view illustrating the state of the memory cell MC. FIG. 8 is a schematic energy band diagram illustrating the state of the memory cell MC. FIG. 9 is a schematic cross-sectional view illustrating the state of the memory cell MC. FIG. 10 is a schematic energy band diagram illustrating the state of the memory cell MC. FIGS. 8 and 10 illustrate the potential energy of electrons in the conduction band of the configurations shown in FIGS. 7 and 9, respectively.

As described with reference to FIG. 4, the gate insulating film 130 of the memory cell MC according to the present embodiment includes the ferroelectric film 131. When a positive polarity voltage and a negative polarity voltage of a predetermined magnitude or more are alternately supplied to the word line WL connected to such a memory cell MC, a hysteresis curve as shown in FIG. 6 is observed. In FIG. 6, states S₁ and S₂ are shown on the hysteresis curve.

The state S₁ is the state of the memory cell MC controlled to the higher state. In the state S₁, the polarizability P is a negative polarizability P₁, and the voltage of the word line WL is the ground voltage V_{SS}. Here, as shown in FIGS. 7 and 8, negative charges are induced on the surface of the ferroelectric film 131 on the semiconductor layer 120 side, and the potential energy of electrons near the surface is high. Here, since positive charges are induced on the surface of the semiconductor layer 120 on the ferroelectric film 131 side and the potential energy of electrons near the surface is high, it is difficult to form an electron channel in the semiconductor layer 120. Therefore, the threshold voltage of the memory cell MC has a positive value.

When a voltage approximately equal to the read pass voltage is supplied to the gate electrode of the memory cell MC in the state S₁, the state of polarization in the ferroelectric film 131 does not change. When the supply of voltage to the gate electrode is interrupted here, the memory cell MC returns to the state S₁.

When a positive polarity voltage of a predetermined magnitude or more is supplied to the gate electrode of the memory cell MC in the state S₁, the direction of polarization in the ferroelectric film 131 is reversed by an electric field between the conductive layer 110 and the semiconductor layer 120, and as shown in FIG. 6, the polarizability P of the ferroelectric film 131 increases. When the voltage of the gate electrode reaches a write voltage VPGM, the polarizability P of the memory cell MC changes to a certain magnitude and becomes saturated. When the supply of voltage to the gate electrode is interrupted here, the memory cell MC transitions to the state S₂.

The state S₂ is a state of the memory cell MC controlled to the lower state. In the state S₂, the polarizability P is a positive polarizability P₂, and the voltage of the word line WL is the ground voltage V_{SS}. Here, as shown in FIGS. 9 and 10, positive charges are induced on the surface of the ferroelectric film 131 on the semiconductor layer 120 side, and the potential energy of electrons near the surface is low. Here, since negative charges are induced on the surface of the semiconductor layer 120 on the ferroelectric film 131 side and the potential energy of electrons near the surface is low, an electron channel is formed in the semiconductor layer 120. Therefore, the threshold voltage of the memory cell MC has a negative value.

When a negative polarity voltage of a predetermined magnitude or more is supplied to the gate electrode of the memory cell MC in the state S₂, the direction of polarization in the ferroelectric film 131 is reversed by the electric field between the conductive layer 110 and the semiconductor layer 120, and as shown in FIG. 6, the polarizability P in the ferroelectric film 131 decreases. When the voltage of the gate electrode reaches an erase voltage Vera, the polarizability P of the memory cell MC changes to a certain magnitude and becomes saturated. When the supply of voltage to the gate electrode is interrupted here, the memory cell MC transitions to the state S₁.

### [Effects]

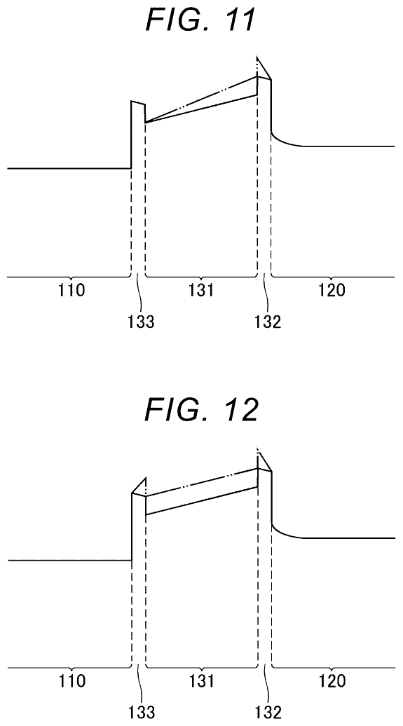

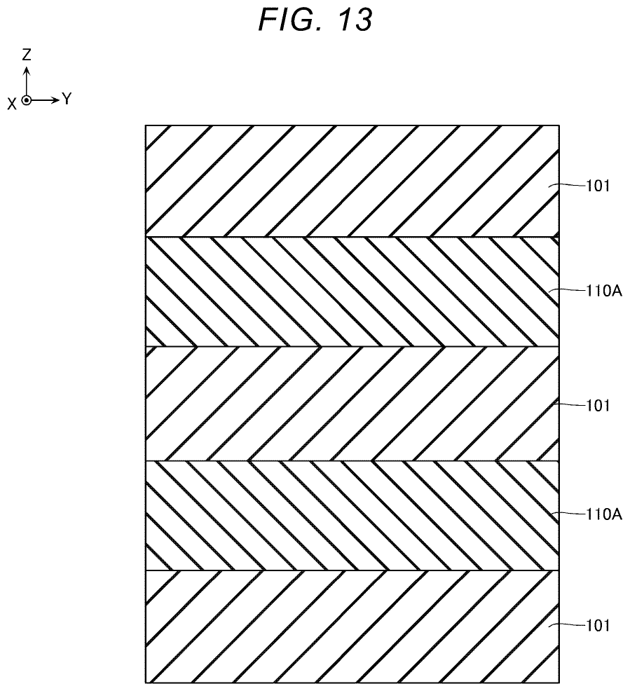

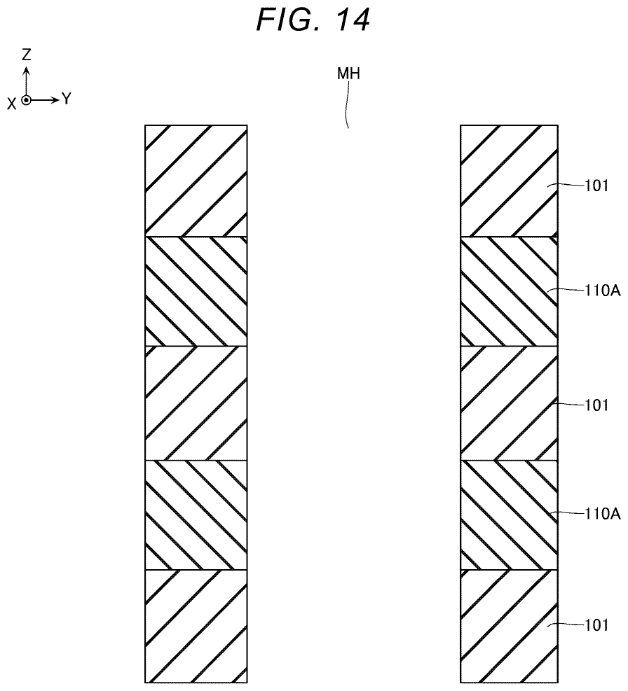

FIGS. 11 and 12 are schematic energy band diagrams illustrating the effects of the first embodiment.

As described with reference to FIG. 4, the ferroelectric film 131 according to the present embodiment includes the additive region 134 that includes the inner peripheral surface of the ferroelectric film 131 and includes the second additive element such as titanium (Ti). According to such a configuration, the crystal structure of the ferroelectric film 131 can be controlled to be orthorhombic, and ferroelectricity can be suitably exhibited.

Here, a trap level due to the second additive element such as titanium (Ti) is formed in the additive region 134. In FIG. 11, a solid line indicates a state before electrons are accumulated in the trap level in the additive region 134, and a two-dot chain line indicates a state after the electrons are accumulated. When electrons are trapped in the additive region 134, an energy gradient in the ferroelectric film 131 becomes steep as shown in FIG. 11 in the state S₁ described with reference to FIGS. 7 and 8. Here, the transition from the state S₁ to the state S₂ will occur at a low voltage. For example, when the transition from the state S₁ to the state S₂ occurs at the read pass voltage V_{READ} described with reference to FIG. 5, erroneous writing occurs in association with execution of the read operation.

Therefore, the ferroelectric film 131 according to the present embodiment includes the additive region 135 that includes the outer peripheral surface of the ferroelectric film 131 and includes the third additive element such as titanium (Ti).

In FIG. 12, a solid line indicates a state before electrons are accumulated in the trap level in the additive regions 134 and 135, and a two-dot chain line indicates a state after the electrons are accumulated. In the present embodiment, electrons are trapped not only on the inner peripheral surface of the ferroelectric film 131 but also on the outer peripheral surface of the ferroelectric film 131. As a result, it is possible to make the energy gradient more gentle in the ferroelectric film 131, as shown in FIG. 12, for example. Accordingly, it is possible to reduce the occurrence of erroneous writing associated with execution of the read operation.

### [Manufacturing Method]

Next, a manufacturing method of the memory die MD will be described with reference to FIGS. 13 to 15. FIGS. 13 to 15 are schematic cross-sectional views illustrating the manufacturing method.

When manufacturing the memory die MD according to the present embodiment, for example, as shown in FIG. 13, a plurality of sacrificial layers 110A and a plurality of insulating layers 101 are formed above the semiconductor substrate 100 described with reference to FIG. 3. The sacrificial layer 110A includes, for example, polycrystalline silicon (Si), silicon nitride (Si₃N₄), and the like. The step is performed by a method such as chemical vapor deposition (CVD).

Next, as shown in FIG. 14, for example, a memory hole MH is formed at a position corresponding to the semiconductor layer 120. The memory hole MH is a through hole extending in the Z direction and penetrating the insulating layer 101 and the sacrificial layer 110A. The step is performed by a method such as reactive ion etching (RIE).

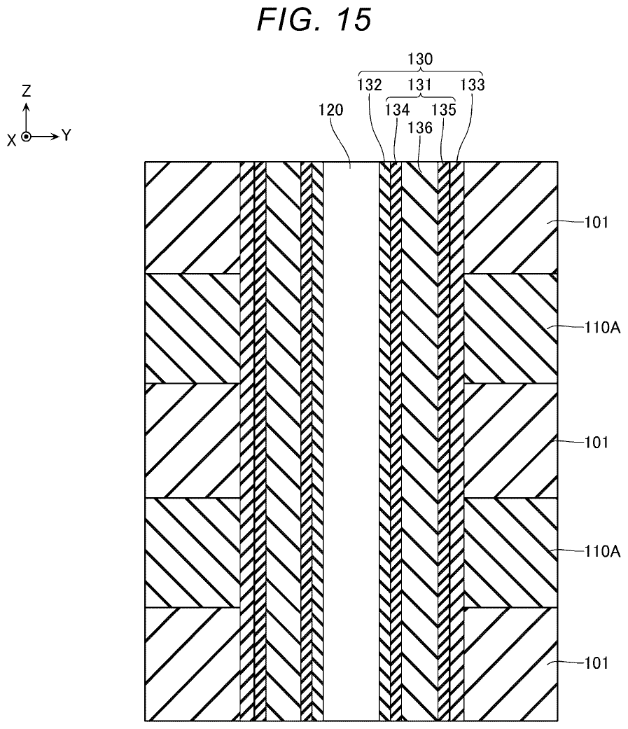

Next, as shown in FIG. 15, for example, the insulating film 133, the ferroelectric film 131, the insulating film 132, and the semiconductor layer 120 are formed on the inner peripheral surface of the memory hole MH. The step is performed by a method such as CVD or atomic layer deposition (ALD).

Thereafter, a structure as described with reference to FIG. 4 is manufactured by forming a groove by RIE or the like at a position corresponding to the electrode 140 described with reference to FIG. 3, removing the sacrificial layer 110A by wet etching or the like through the groove, and forming the conductive layer 110 by means such as CVD. The structure as described with reference to FIG. 3 is manufactured by forming the insulating film 141, the electrode 140, the bit line BL, or the like.

### Second Embodiment

As described above, the ferroelectric film 131 according to the first embodiment includes the additive region 135 that includes the outer peripheral surface of the ferroelectric film 131, thereby making the energy gradient more gentle in the ferroelectric film 131. However, such a configuration is merely an example, and the specific configuration can be adjusted as appropriate. For example, the additive region 135 may be provided in the vicinity of the outer peripheral surface of the ferroelectric film 131, and does not need to include the outer peripheral surface. Hereinafter, such a configuration will be illustrated as a semiconductor memory device according to the second embodiment.

### [Configuration]

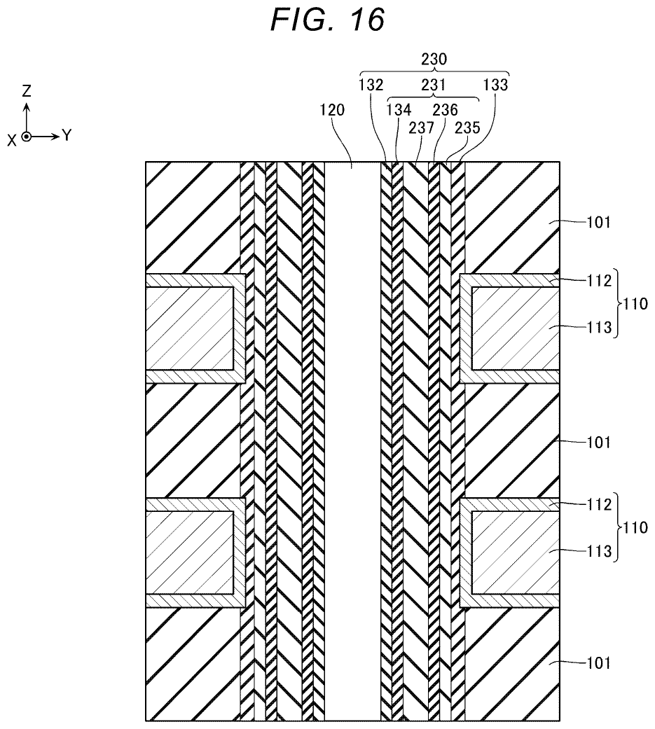

FIG. 16 is a schematic cross-sectional view showing a partial configuration of the semiconductor memory device according to the second embodiment.

The semiconductor memory device according to the second embodiment is basically configured similarly to the semiconductor memory device according to the first embodiment. However, the semiconductor memory device according to the second embodiment includes a gate insulating film 230 instead of the gate insulating film 130. The gate insulating film 230 is basically configured similarly to the gate insulating film 130. However, the gate insulating film 230 includes a ferroelectric film 231 instead of the ferroelectric film 131.

The ferroelectric film 231 is basically configured similarly to the ferroelectric film 131. However, the ferroelectric film 231 includes the additive region 134 including the inner peripheral surface of the ferroelectric film 231, a region 235 including the outer peripheral surface of the ferroelectric film 231, an additive region 236 provided between the additive region 134 and the region 235, and a memory region 237 provided between the additive region 134 and the additive region 236.

The additive region 236 is configured similarly to the additive region 135 described with reference to FIG. 4.

The region 235 may or may not include the third additive element, in addition to the first additive element described above. When the region 235 includes the third additive element, the concentration of the third additive element in the region 235 is lower than the concentration of the third additive element in the additive region 236. When the region 235 includes the third additive element, a boundary between the region 235 and the additive region 236 may be, for example, a position where the concentration of the third additive element is half of a peak value. When the region 235 does not include the third additive element, a boundary between the region 235 and the additive region 236 may be, for example, a boundary between a region including the third additive element and a region not including the third additive element, or may be a boundary between a region where the third additive element can be detected and a region where the third additive element cannot be detected.

The memory region 237 is configured similarly to the memory region 136 described with reference to FIG. 4.

### [Manufacturing Method]

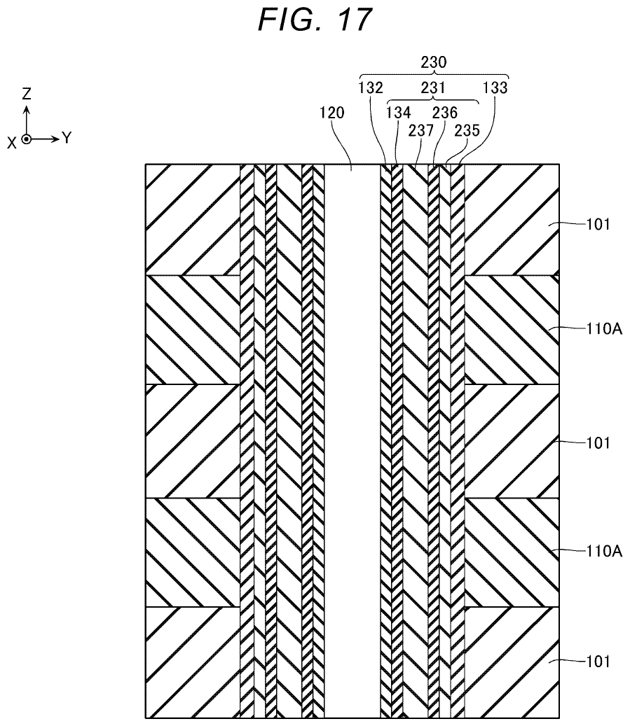

Next, with reference to FIG. 17, a manufacturing method of the semiconductor memory device according to the second embodiment will be described. FIG. 17 is a schematic cross-sectional view illustrating the manufacturing method.

The semiconductor memory device according to the second embodiment is basically manufactured similarly to the semiconductor memory device according to the first embodiment. However, when manufacturing the semiconductor memory device according to the second embodiment, the gate insulating film 230 is formed instead of the gate insulating film 130 as shown in FIG. 17 in the step described with reference to FIG. 15.

### Third Embodiment

### [Configuration]

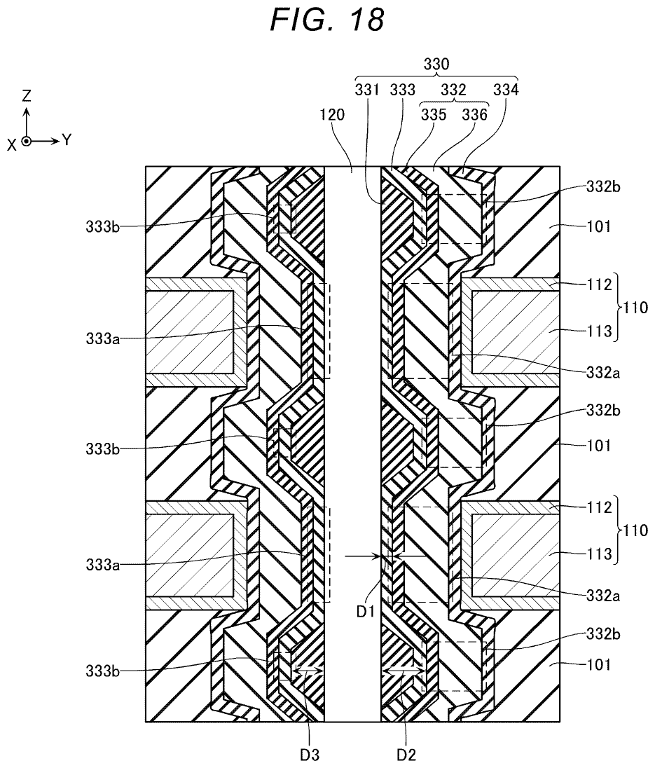

Next, with reference to FIG. 18, a semiconductor memory device according to a third embodiment will be described. FIG. 18 is a schematic cross-sectional view showing a partial configuration of the semiconductor memory device according to the third embodiment.

The semiconductor memory device according to the third embodiment is basically configured similarly to the semiconductor memory device according to the first embodiment. However, the semiconductor memory device according to the third embodiment includes a gate insulating film 330 instead of the gate insulating film 130.

The gate insulating film 330 is basically configured similarly to the gate insulating film 130.

However, an inner diameter and an outer diameter of a portion of the gate insulating film 330 provided at a height position corresponding to the insulating layer 101 are greater than an inner diameter and an outer diameter of a portion provided at a height position corresponding to the conductive layer 110, respectively.

The gate insulating film 330 includes a plurality of insulating members 331 arranged in the Z direction corresponding to the plurality of insulating layers 101, a ferroelectric film 332 extending in the Z direction over a range in the Z direction corresponding to the plurality of conductive layers 110 along the outer peripheral surfaces of the plurality of insulating members 331 and the semiconductor layer 120, an insulating film 333 (boundary layer) extending in the Z direction over a range in the Z direction corresponding to the plurality of conductive layers 110 along the inner peripheral surface of the ferroelectric film 332, and an insulating film 334 (boundary layer) extending in the Z direction over a range in the Z direction corresponding to the plurality of conductive layers 110 along the outer peripheral surface of the ferroelectric film 332.

The insulating member 331 includes, for example, silicon oxide (SiO₂). The insulating member 331 has a substantially annular shape. The inner peripheral surface of the insulating member 331 is connected to the outer peripheral surface of the semiconductor layer 120.

The ferroelectric film 332 is basically configured similarly to the ferroelectric film 131. However, an inner diameter and an outer diameter of a portion 332b of the ferroelectric film 332 provided at a height position corresponding to the insulating layer 101 are greater than an inner diameter and an outer diameter of a portion 332a provided at a height position corresponding to the conductive layer 110, respectively.

That is, the ferroelectric film 332 includes a plurality of portions 332a provided at a plurality of height positions corresponding to the plurality of conductive layers 110, and a plurality of portions 332b provided at a plurality of height positions corresponding to the plurality of insulating layers 101. The inner diameter of the plurality of portions 332b is larger than the inner diameter of the plurality of portions 332a. That is, a distance D2 from the inner peripheral surface (the surface on the semiconductor layer 120 side) of the plurality of portions 332b to the semiconductor layer 120 is larger than a distance D1 from the inner peripheral surface (the surface on the semiconductor layer 120 side) of the plurality of portions 332a to the semiconductor layer 120. The difference between the distance D2 and the distance D1 may be, for example, 2 nm or more. The outer diameter of the plurality of portions 332b is larger than the outer diameter of the plurality of portions 332a.

The ferroelectric film 332 includes an additive region 335 including the inner peripheral surface of the ferroelectric film 332, and a memory region 336 provided between the additive region 335 and the conductive layer 110. The additive region 335 and the memory region 336 are formed substantially similarly to the additive region 134 and the memory region 136, respectively. However, an inner diameter and an outer diameter of a portion of the additive region 335 provided at a height position corresponding to the insulating layer 101 are greater than an inner diameter and an outer diameter of a portion provided at a height position corresponding to the conductive layer 110, respectively. An inner diameter and an outer diameter of a portion of the memory region 336 provided at a height position corresponding to the insulating layer 101 are greater than an inner diameter and an outer diameter of a portion provided at a height position corresponding to the conductive layer 110, respectively.

The insulating film 333 is basically configured substantially similarly to the insulating film 132. However, an inner diameter and an outer diameter of a portion 333b of the insulating film 333 provided at a height position corresponding to the insulating layer 101 are greater than an inner diameter and an outer diameter of a portion 333a provided at a height position corresponding to the conductive layer 110, respectively.

That is, the insulating film 333 includes a plurality of portions 333a provided at a plurality of height positions corresponding to the plurality of conductive layers 110, and a plurality of portions 333b provided at a plurality of height positions corresponding to the plurality of insulating layers 101. The inner diameter of the plurality of portions 333b is larger than the inner diameter of the plurality of portions 333a. The outer diameter of the plurality of portions 333b is larger than the outer diameter of the plurality of portions 333a.

A distance D3 from the inner peripheral surface (the surface on the semiconductor layer 120 side) of the plurality of portions 333b to the semiconductor layer 120 is larger than a distance from the inner peripheral surface (the surface on the semiconductor layer 120 side) of the plurality of portions 333a to the semiconductor layer 120. For example, in the illustrated example, the plurality of portions 333a are each connected to the outer peripheral surface of the semiconductor layer 120, and the distance from the inner peripheral surfaces of the plurality of portions 333a to the semiconductor layer 120 is zero. On the other hand, since the plurality of portions 333b are each separated from the semiconductor layer 120 via the insulating member 331, the distance D3 is not zero.

The insulating film 334 is basically configured substantially similarly to the insulating film 133. However, an inner diameter and an outer diameter of a portion of the insulating film 334 provided at a height position corresponding to the insulating layer 101 are greater than an inner diameter and an outer diameter of a portion provided at a height position corresponding to the conductive layer 110, respectively.

### [Effects]

As described with reference to FIG. 4, in the first embodiment, the additive region 134 of the ferroelectric film 131 is formed in a substantially cylindrical shape. Here, as described above, an electron trap level is formed in the additive region 134. When the insulating film 132 includes silicon oxynitride (SiON), an electron trap level is also formed in the insulating film 132. In such a configuration, a tunnel current is generated every time a write operation and an erase operation are repeated, and electrons are accumulated in a portion of the additive region 134 and the insulating film 132 provided at a height position corresponding to the insulating layer 101. Thus, the threshold voltage of the memory cell MC may not be suitably controlled. The current flowing through the semiconductor layer 120 decreases.

Therefore, in the third embodiment, a portion of the additive region 335 provided at a height position corresponding to the insulating layer 101 and the portion 333b of the insulating film 333 are spaced apart from the semiconductor layer 120. Accordingly, it is possible to reduce electron tunneling from the semiconductor layer 120 and reduce the deterioration of the threshold voltage characteristics due to an increase in the number of write/erase operations. It is possible to reduce a decrease in the current flowing through the semiconductor layer 120.

### [Manufacturing Method]

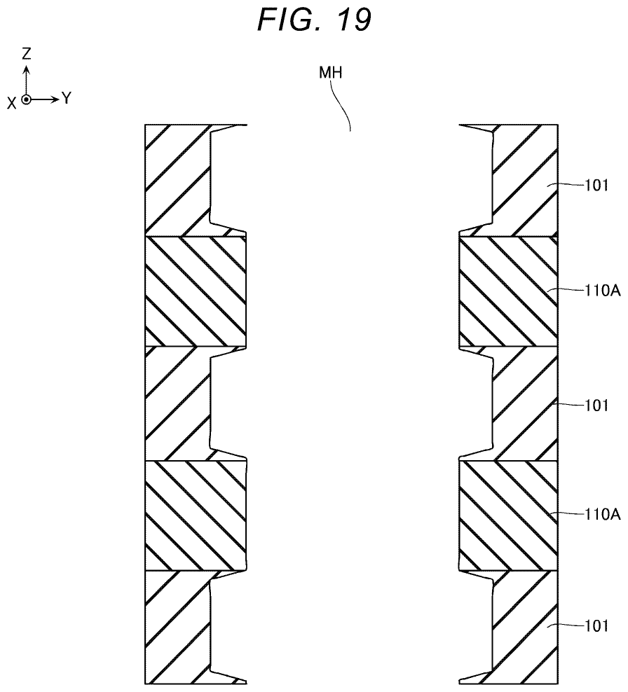

Next, with reference to FIGS. 19 to 23, a manufacturing method of the semiconductor memory device according to the third embodiment will be described. FIGS. 19 to 23 are schematic cross-sectional views illustrating the manufacturing method.

When manufacturing the semiconductor memory device according to the third embodiment, for example, among the manufacturing steps of the semiconductor memory device according to the first embodiment, the steps up to the steps described with reference to FIG. 14 are executed.

Next, as shown in FIG. 19, for example, a part of the insulating layer 101 is removed via the memory hole MH. The step is performed by a method such as wet etching.

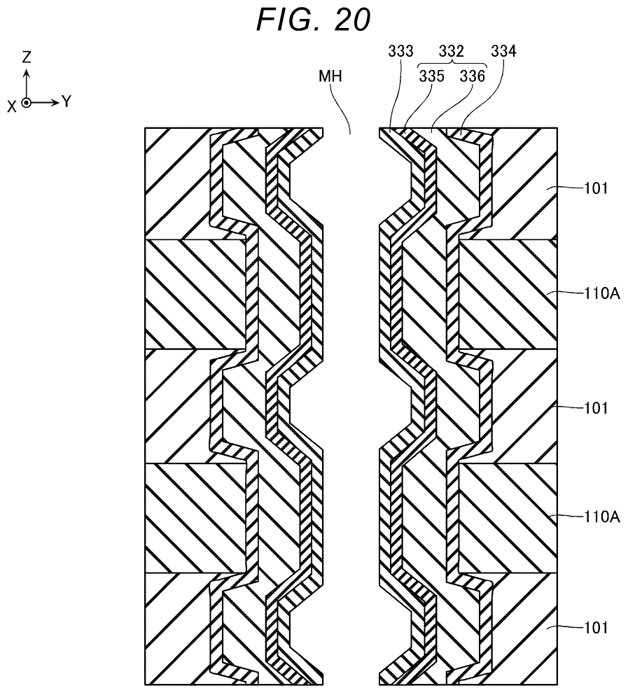

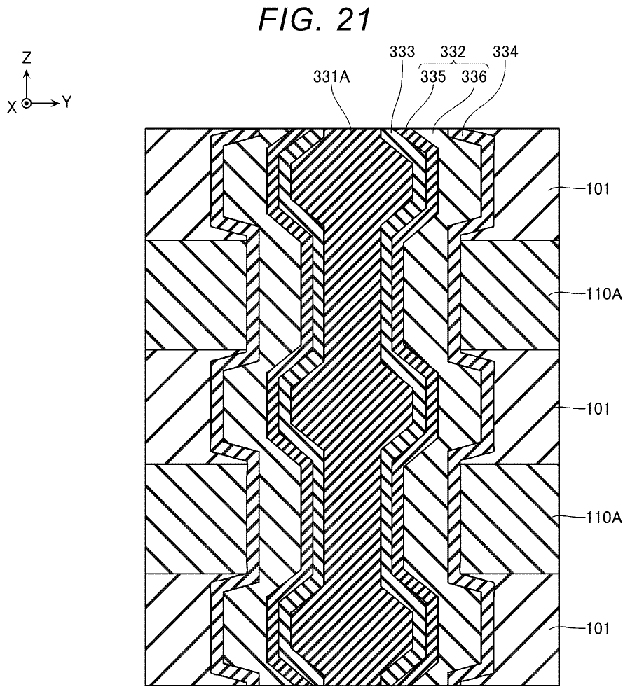

Next, as shown in FIG. 20, for example, the insulating film 334, the ferroelectric film 332, and the insulating film 333 are formed on the inner peripheral surface of the memory hole MH. The step is performed by a method such as CVD or ALD.

Next, as shown in FIG. 21, for example, the memory hole MH is filled with an insulating member 331A. The step is performed by a method such as CVD.

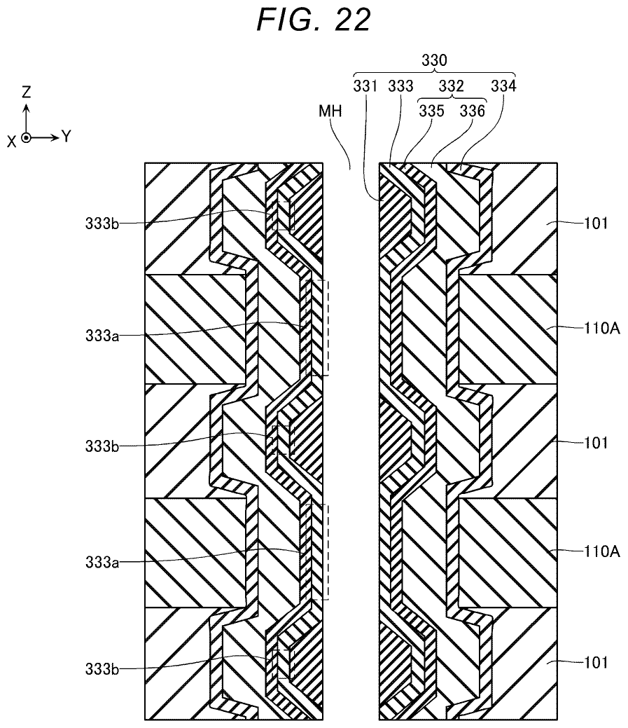

Next, as shown in FIG. 22, for example, a part of the insulating member 331A is removed. Here, the portion 333a of the insulating film 333 is exposed inside the memory hole MH. The insulating member 331A is divided into a plurality of insulating members 331 arranged in the Z direction. The step is performed by a method such as RIE.

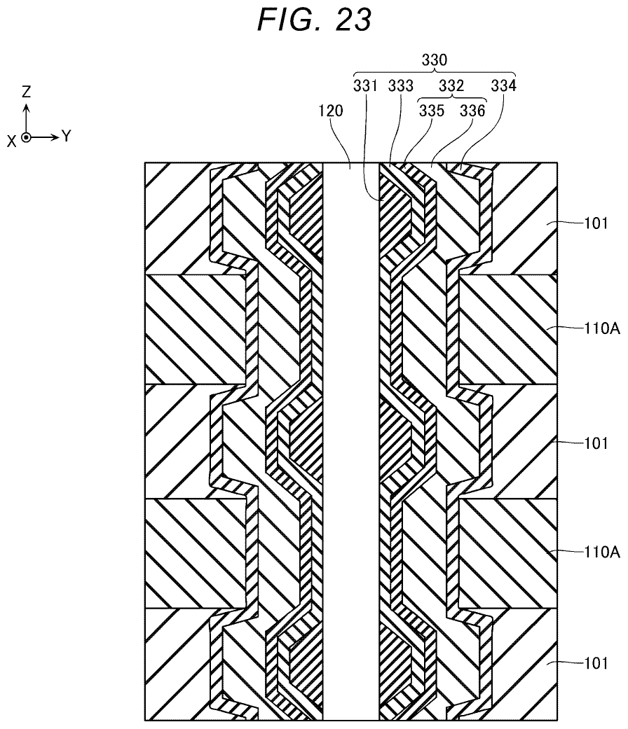

Next, as shown in FIG. 23, for example, the semiconductor layer 120 is formed inside the memory hole MH. The step is performed by a method such as CVD.

Thereafter, a structure as described with reference to FIG. 18 is manufactured by forming a groove by RIE or the like at a position corresponding to the electrode 140 described with reference to FIG. 3, removing the sacrificial layer 110A by wet etching or the like through the groove, forming the conductive layer 110 by means such as CVD.

### Fourth Embodiment

### [Configuration]

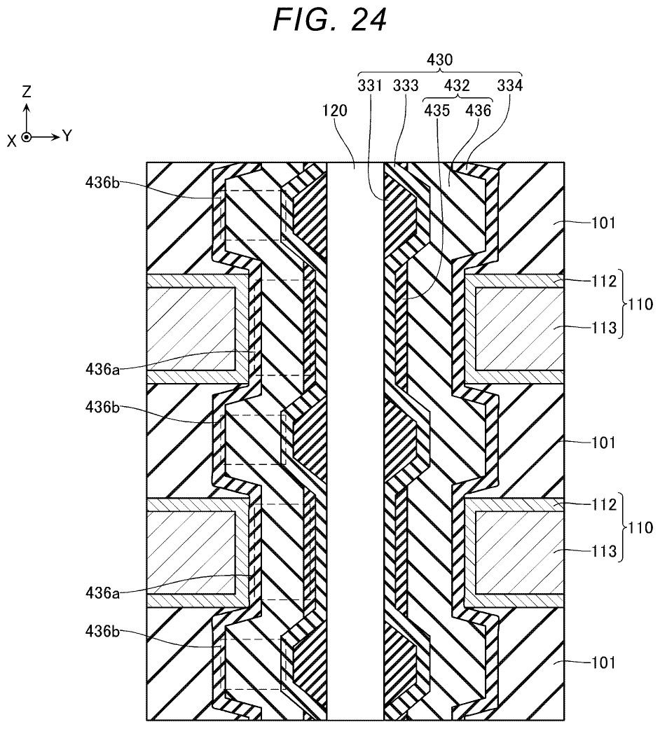

Next, with reference to FIG. 24, a semiconductor memory device according to a fourth embodiment will be described. FIG. 24 is a schematic cross-sectional view showing a partial configuration of the semiconductor memory device according to the fourth embodiment.

The semiconductor memory device according to the fourth embodiment is basically configured similarly to the semiconductor memory device according to the third embodiment. However, the semiconductor memory device according to the fourth embodiment includes a gate insulating film 430 instead of the gate insulating film 330. The gate insulating film 430 is basically configured similarly to the gate insulating film 330. However, the gate insulating film 430 includes a ferroelectric film 432 instead of the ferroelectric film 332.

The ferroelectric film 432 is basically configured similarly to the ferroelectric film 332. However, the ferroelectric film 432 includes a plurality of additive regions 435 provided at a height position corresponding to the conductive layer 110 and including the inner peripheral surface of the ferroelectric film 432, and a memory region 436 provided between the plurality of additive regions 435 and the conductive layer 110.

The plurality of additive regions 435 are basically configured similarly to the additive region 335. However, the plurality of additive regions 435 are spaced apart from each other in the Z direction and are arranged in the Z direction corresponding to the conductive layer 110. Each of the additive regions 435 has a substantially annular shape.

The memory region 436 is basically configured similarly to the memory region 336. However, an inner diameter and an outer diameter of a portion 436b of the memory region 436 provided at a height position corresponding to the insulating layer 101 are greater than an inner diameter and an outer diameter of a portion 436a provided at a height position corresponding to the conductive layer 110, respectively.

That is, the memory region 436 includes a plurality of portions 436a provided at a plurality of height positions corresponding to the plurality of conductive layers 110, and a plurality of portions 436b provided at a plurality of height positions corresponding to the plurality of insulating layers 101. The inner diameter of the plurality of portions 436b is larger than the inner diameter of the plurality of portions 436a. The outer diameter of the plurality of portions 436b is larger than the outer diameter of the plurality of portions 436a.

Here, the portion 436a is in contact with the additive region 435. Therefore, the crystal structure in the portion 436a is controlled by the additive region 435 to mainly include orthorhombic crystals. As a result, the portion 436a exhibits ferroelectricity. On the other hand, the portion 436b is not in contact with the additive region 435. Therefore, the crystal structure in the portion 436b mainly includes a crystal structure other than orthorhombic crystals. Therefore, the portion 436b does not exhibit ferroelectricity.

### [Effects]

According to the semiconductor memory device according to the fourth embodiment, it is possible to achieve the same effects as the semiconductor memory device according to the third embodiment.

According to such a configuration, it is possible to divide the region exhibiting ferroelectricity in the Z direction for each memory cell MC. Accordingly, it is possible to reduce polarization reversal in the portion of the ferroelectric film 432 provided at a height position corresponding to the insulating layer 101.

### [Manufacturing Method]

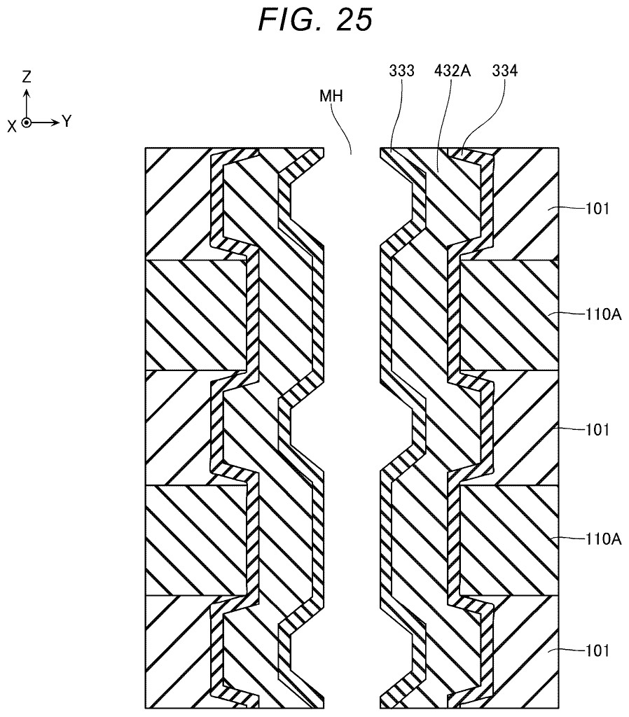

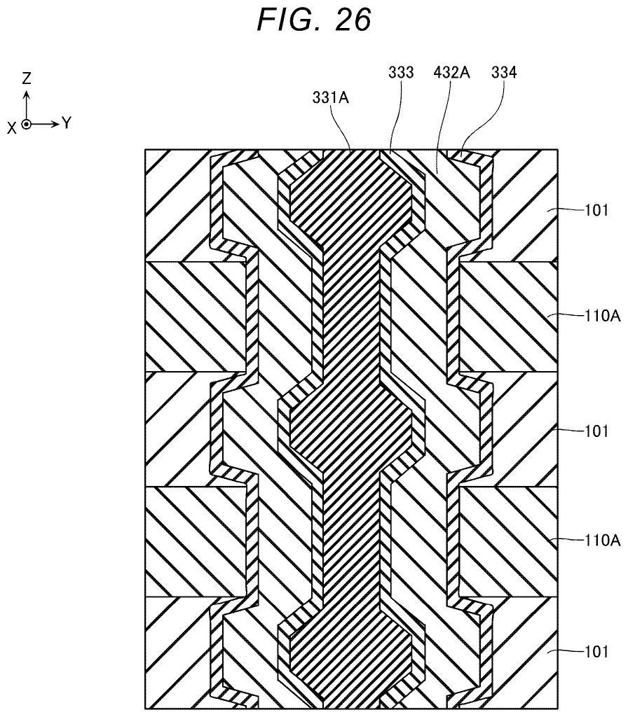

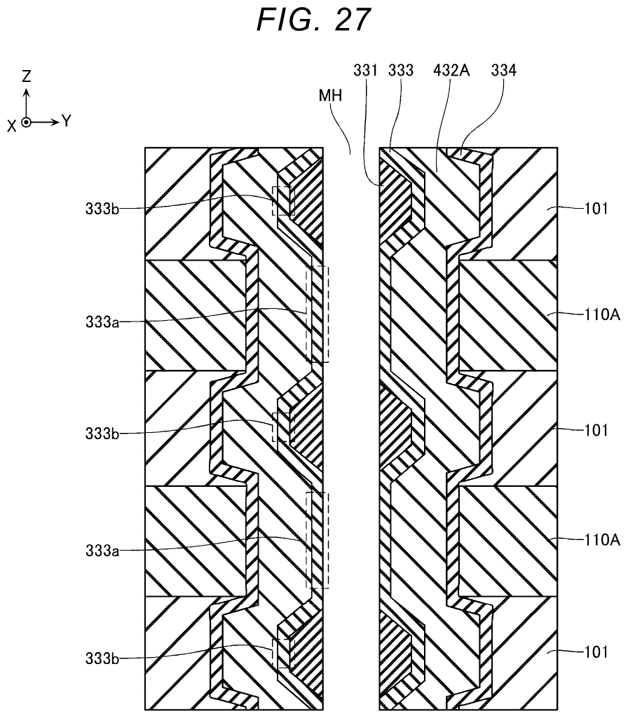

Next, with reference to FIGS. 25 to 29, a manufacturing method of the semiconductor memory device according to the fourth embodiment will be described. FIGS. 25 to 29 are schematic cross-sectional views illustrating the manufacturing method.

When manufacturing the semiconductor memory device according to the fourth embodiment, for example, among the manufacturing steps of the semiconductor memory device according to the third embodiment, the steps up to the steps described with reference to FIG. 19 are executed.

Next, as shown in FIG. 25, for example, the insulating film 334, a ferroelectric film 432A, and the insulating film 333 are formed on the inner peripheral surface of the memory hole MH. The step is performed by a method such as CVD or ALD.

Next, as shown in FIG. 26, for example, the memory hole MH is filled with the insulating member 331A. The step is performed by a method such as CVD.

Next, as shown in FIG. 27, for example, a part of the insulating member 331A is removed. Here, the portion 333a of the insulating film 333 is exposed inside the memory hole MH. The insulating member 331A is divided into a plurality of insulating members 331 arranged in the Z direction.

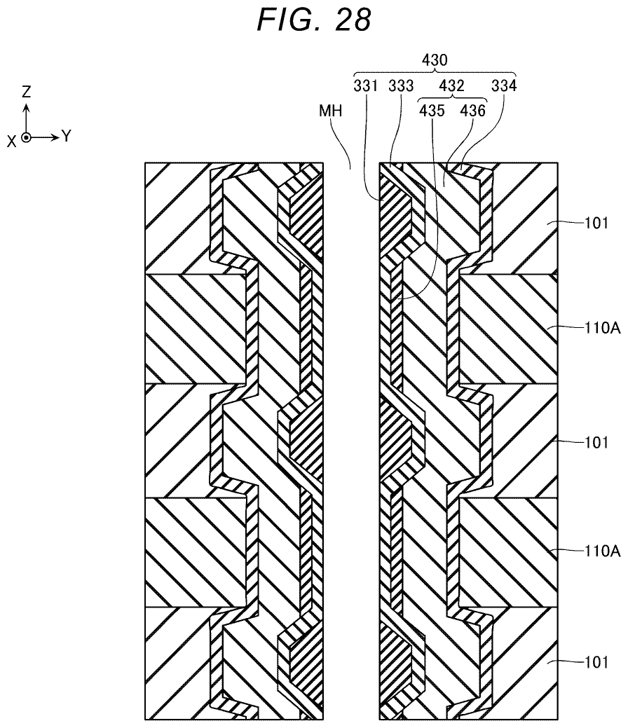

Next, as shown in FIG. 28, for example, the second additive element is added to the ferroelectric film 432A via the insulating film 333. Thus, a plurality of additive regions 435 are formed.

In the example of FIG. 28, the insulating member 331 including silicon oxide (SiO₂) and the insulating film 333 including silicon oxynitride (SiON) are exposed inside the memory hole MH. Here, the second additive element such as titanium (Ti) is difficult to adhere to silicon oxide (SiO₂), but is easy to adhere to silicon oxynitride (SiON). Therefore, the additive region 435 is formed in a portion of the ferroelectric film 432A that is not covered by the insulating member 331 (a portion provided at a height position corresponding to the sacrificial layer 110A). On the other hand, an additive region is not formed in a portion of the ferroelectric film 432A that is covered by the insulating member 331 (a portion provided at a height position corresponding to the insulating layer 101).

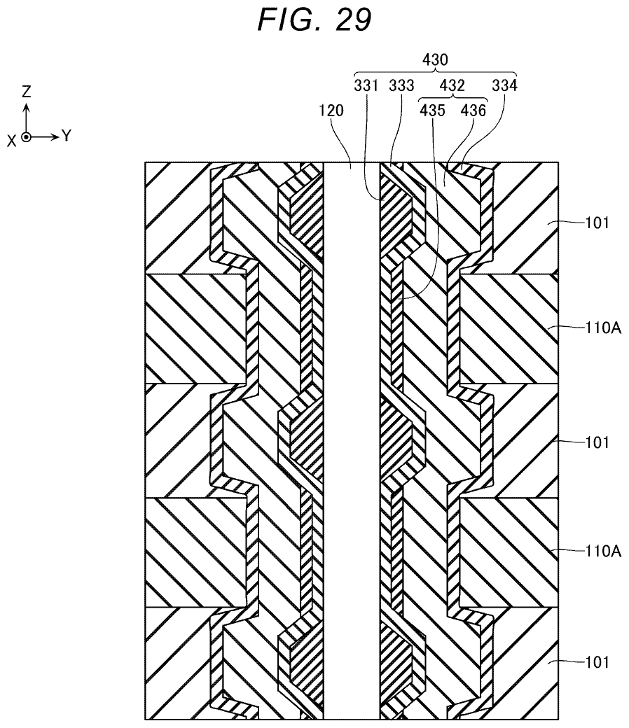

Next, as shown in FIG. 29, for example, the semiconductor layer 120 is formed inside the memory hole MH. The step is performed by a method such as CVD.

Thereafter, a structure as described with reference to FIG. 24 is manufactured by forming a groove by RIE or the like at a position corresponding to the electrode 140 described with reference to FIG. 3, removing the sacrificial layer 110A by wet etching or the like through the groove, and forming the conductive layer 110 by means such as CVD.

### Fifth Embodiment

### [Configuration]

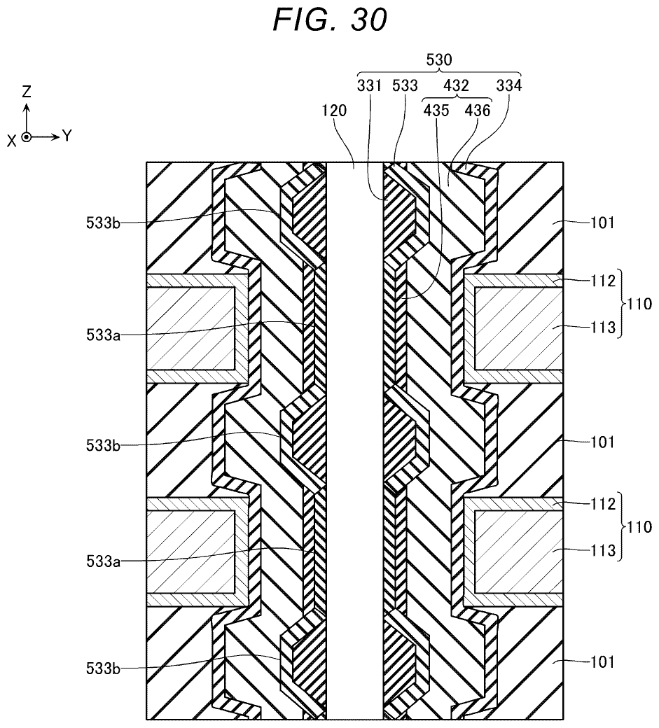

Next, with reference to FIG. 30, a semiconductor memory device according to a fifth embodiment will be described. FIG. 30 is a schematic cross-sectional view showing a partial configuration of the semiconductor memory device according to the fifth embodiment.

The semiconductor memory device according to the fifth embodiment is basically configured similarly to the semiconductor memory device according to the fourth embodiment. However, the semiconductor memory device according to the fifth embodiment includes a gate insulating film 530 instead of the gate insulating film 430. The gate insulating film 530 is basically configured similarly to the gate insulating film 430. However, the gate insulating film 530 includes an insulating film 533 instead of the insulating film 333.

The insulating film 533 is basically configured similarly to the insulating film 333. However, the insulating film 533 includes a plurality of portions 533a and a plurality of portions 533b instead of the plurality of portions 333a and the plurality of portions 333b. The plurality of portions 533a and the plurality of portions 533b are basically configured similarly to the plurality of portions 333a and the plurality of portions 333b, respectively. However, the portion 533a includes, for example, silicon oxynitride (SiON). The portion 533b includes, for example, silicon nitride (SiN).

### [Effects]

According to the semiconductor memory device according to the fifth embodiment, it is possible to achieve the same effects as the semiconductor memory device according to the fourth embodiment.

### [Manufacturing Method]

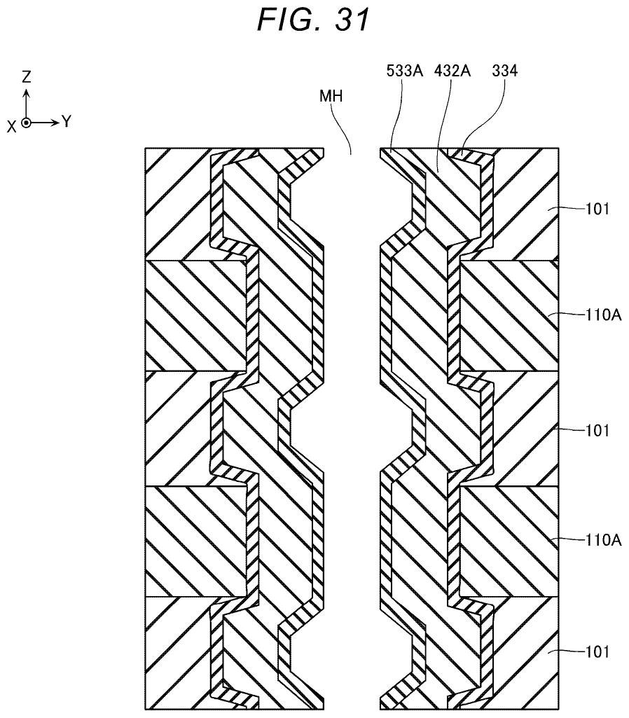

Next, with reference to FIGS. 31 to 33, a manufacturing method of the semiconductor memory device according to the fifth embodiment will be described. FIGS. 31 to 33 are schematic cross-sectional views illustrating the manufacturing method.

When manufacturing the semiconductor memory device according to the fifth embodiment, for example, among the manufacturing steps of the semiconductor memory device according to the fourth embodiment, the steps up to the steps described with reference to FIG. 19 are executed.

Next, as shown in FIG. 31, for example, the insulating film 334, the ferroelectric film 432A, and an insulating film 533A are formed on the inner peripheral surface of the memory hole MH. The insulating film 533A includes, for example, silicon nitride (SiN). The step is performed by a method such as CVD.

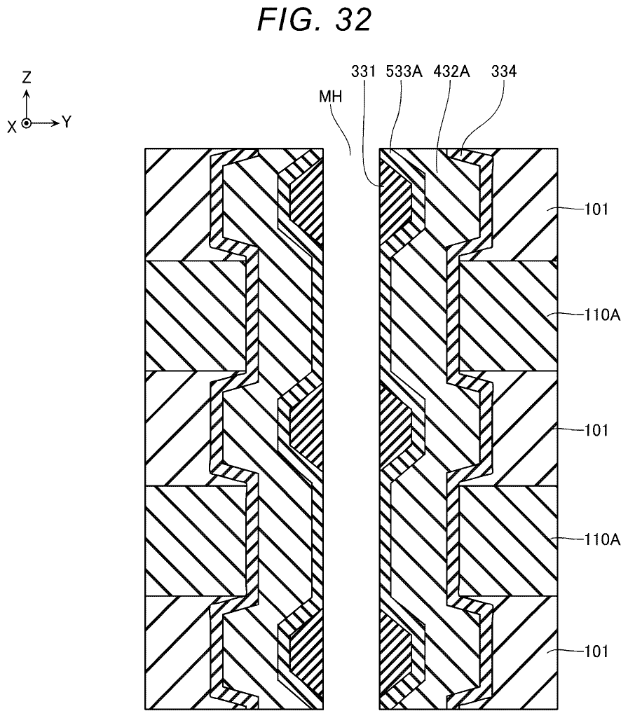

Next, for example, among the manufacturing steps of the semiconductor memory device according to the fourth embodiment, the steps described with reference to FIGS. 21 and 22 are executed. Thus, a structure as shown in FIG. 32 is formed.

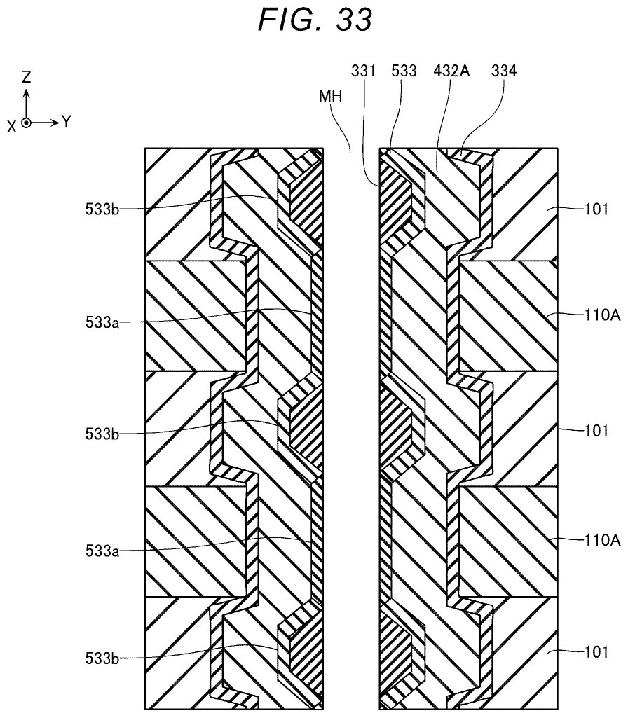

Next, as shown in FIG. 33, for example, the insulating film 533 is formed. Here, the surface of the insulating film 533A exposed to the memory hole MH is oxidized by a method such as thermal oxidation, thereby forming a plurality of portions 533a. Thus, the insulating film 533 is formed.

Thereafter, for example, the structure as described with reference to FIG. 30 is manufactured, by executing the steps from the step described with reference to FIG. 28, among the manufacturing steps of the semiconductor memory device according to the fourth embodiment.

### Sixth Embodiment

### [Configuration]

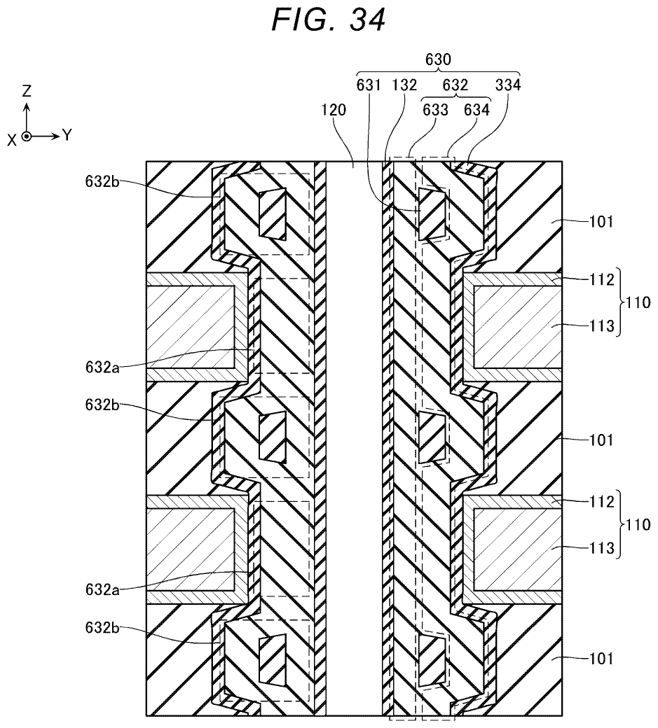

Next, with reference to FIG. 34, a semiconductor memory device according to a sixth embodiment will be described. FIG. 34 is a schematic cross-sectional view showing a partial configuration of the semiconductor memory device according to the sixth embodiment.

The semiconductor memory device according to the sixth embodiment is basically configured similarly to the semiconductor memory device according to the first embodiment. However, the semiconductor memory device according to the sixth embodiment includes a gate insulating film 630 instead of the gate insulating film 130.

The gate insulating film 630 is basically configured similarly to the gate insulating film 130.

However, the outer diameter of a portion of the gate insulating film 630 provided at a height position corresponding to the insulating layer 101 is larger than the outer diameter of a portion provided at a height position corresponding to the conductive layer 110.

The gate insulating film 630 includes a plurality of insulating members 631 arranged in the Z direction corresponding to the plurality of insulating layers 101, a ferroelectric film 632 extending in the Z direction over a range in the Z direction corresponding to the plurality of conductive layers 110 along the plurality of insulating members 631 and the semiconductor layer 120, the substantially cylindrical insulating film 132 extending in the Z direction over a range in the Z direction corresponding to the plurality of conductive layers 110 along the inner peripheral surface of the ferroelectric film 632, and the insulating film 334 extending in the Z direction over a range in the Z direction corresponding to the plurality of conductive layers 110 along the outer peripheral surface of the ferroelectric film 632.

The insulating member 631 includes, for example, material that has a larger equivalent oxide thickness (EOT) than the ferroelectric film 632 of silicon oxide (SiO₂) or the like and has a lower dielectric constant than the ferroelectric film 632. The insulating member 631 has a substantially annular shape. The film thickness (radial length) of the insulating member 631 may be, for example, 1 nm or more. The film thickness of the insulating member 631 may be defined as, for example, the distance between the surface of the insulating member 631 on the semiconductor layer 120 side and the surface of the insulating member 631 on the conductive layer 110 side.

The ferroelectric film 632 is basically configured similarly to the ferroelectric film 131. However, the outer diameter of a portion 632b of the ferroelectric film 632 provided at a height position corresponding to the insulating layer 101 is larger than the outer diameter of a portion 632a provided at a height position corresponding to the conductive layer 110.

That is, the ferroelectric film 632 includes a plurality of portions 632a provided at a plurality of height positions corresponding to the plurality of conductive layers 110, and a plurality of portions 632b provided at a plurality of height positions corresponding to the plurality of insulating layers 101. The inner diameters of the plurality of portions 632b substantially match the inner diameters of the plurality of portions 632a. The outer diameters of the plurality of portions 632b are larger than the outer diameters of the plurality of portions 632a.

The portion 632a mainly includes orthorhombic crystals and exhibits ferroelectricity. On the other hand, the portion 632b mainly includes a crystal structure other than orthorhombic crystals, and does not exhibit ferroelectricity. Each of the plurality of portions 632b is divided into two portions arranged in the radial direction by the insulating member 631.

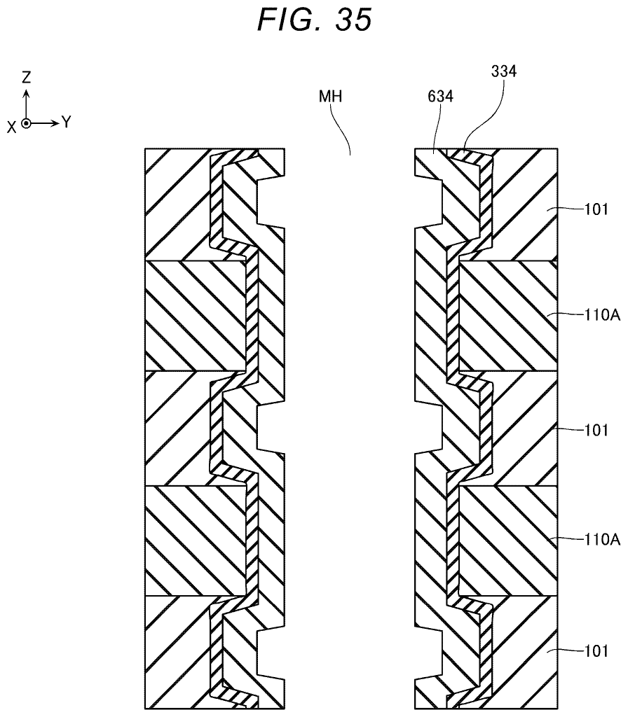

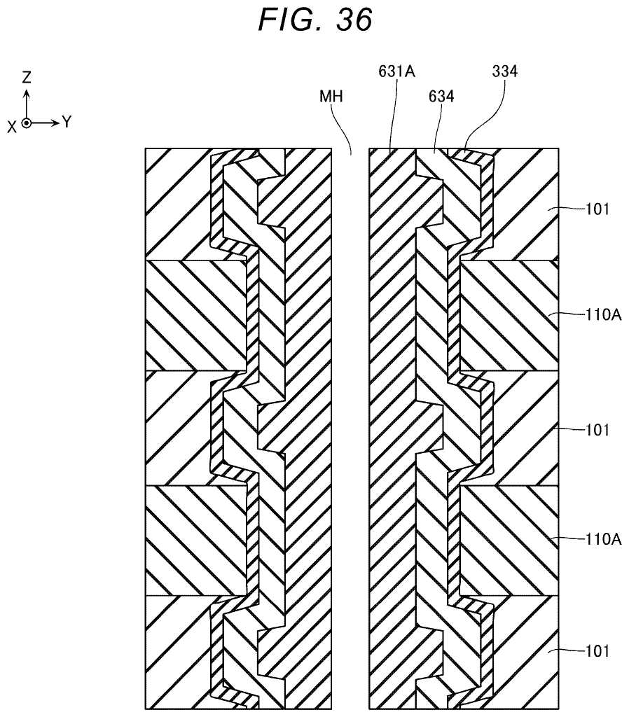

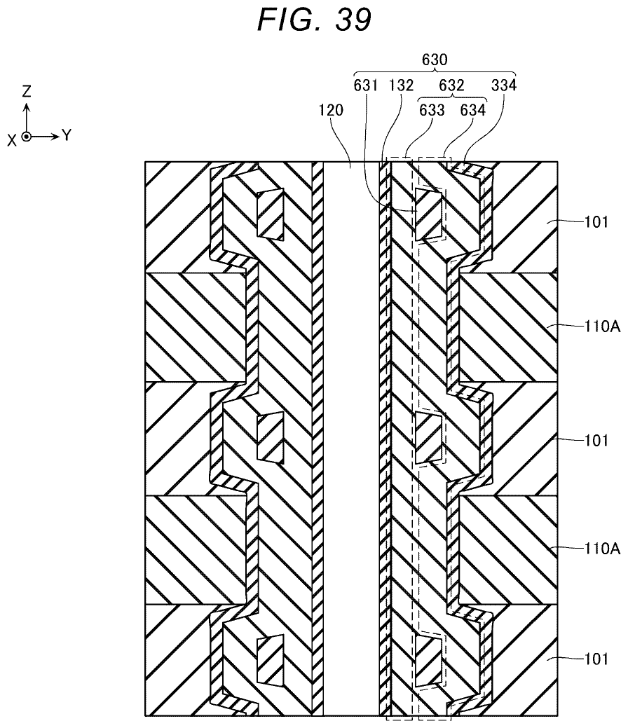

The ferroelectric film 632 includes a region 633 provided on the inner peripheral surface side of the ferroelectric film 632, and a region 634 provided on the outer peripheral surface side of the ferroelectric film 632. The region 634 is a region of the ferroelectric film 632 that is formed in a step described later with reference to FIG. 35. The region 633 is a region of the ferroelectric film 632 that is formed in a step described later with reference to FIG. 39.

The region 633 has a substantially cylindrical shape extending in the Z direction over a range in the Z direction corresponding to the plurality of conductive layers 110 along the outer peripheral surface of the semiconductor layer 120.

The region 634 extends in the Z direction over a range in the Z direction corresponding to the plurality of conductive layers 110 along the outer peripheral surfaces of the region 633 and the insulating member 631. An inner diameter and an outer diameter of a portion of the region 634 provided at a height position corresponding to the insulating layer 101 are greater than an inner diameter and an outer diameter of a portion provided at a height position corresponding to the conductive layer 110, respectively.

A distance from the inner peripheral surface (the surface on the semiconductor layer 120 side) of the plurality of portions of the region 634 corresponding to the plurality of insulating layers 101 to the region 633 is larger than a distance from the inner peripheral surface (the surface on the semiconductor layer 120 side) of the plurality of portions corresponding to the plurality of conductive layers 110 to the region 633. For example, in the illustrated example, the plurality of portions corresponding to the plurality of conductive layers 110 are each connected to the outer peripheral surface of the region 633, and the distance from the inner peripheral surfaces of the plurality of portions corresponding to the plurality of conductive layers 110 to the region 633 is zero. On the other hand, since the plurality of portions corresponding to the plurality of insulating layers 101 are each separated from the region 633, the distance is not zero.

The thickness (radial lengths) of the region 633 and the region 634 may each be less than 8 nm. The total thickness of the region 633 and the region 634 may be 8 nm or more. Then, the thickness of the portion 632a of the ferroelectric film 632 is 8 nm or more. On the other hand, the portion 632b of the ferroelectric film 632 is divided into two portions each having a thickness of less than 8 nm.

The thickness (radial lengths) of the region 633 and the region 634 can be defined by various methods. For example, in the present embodiment, a distance between the insulating member 631 and the surface of the ferroelectric film 632 on the semiconductor layer 120 side may be the thickness of the region 633. A distance between the insulating member 631 and the surface of the ferroelectric film 632 on the conductive layer 110 side may be the thickness of the region 634.

### [Effects]

As described with reference to FIG. 4, in the first embodiment, the ferroelectric film 131 is formed into a substantially cylindrical shape. In such a configuration, for example, during a write operation or an erase operation, there is a possibility that polarization reversal may occur in a portion of the ferroelectric film 131 provided at a height position corresponding to the insulating layer 101 or the adjacent word lines WL (the word lines WL adjacent to the selected word line WL in the Z direction) due to the fringe electric field of the conductive layer 110.

Therefore, in the sixth embodiment, the insulating member 631 having a larger EOT than the ferroelectric film 632 is provided at a height position corresponding to the insulating layer 101 of the gate insulating film 630. According to such a configuration, the lines of electric force from the conductive layer 110 avoid the insulating layer 101 and reach the semiconductor layer 120, so that it is possible to reduce polarization reversal in the portion of the ferroelectric film 632 provided at a height position corresponding to the insulating layer 101 or the adjacent word line WL.

In the sixth embodiment, the thickness of the portion of the ferroelectric film 632 provided at a height position corresponding to the conductive layer 110 may be 8 nm or more. A portion of the ferroelectric film 632 provided at a height position corresponding to the insulating layer 101 may be divided into two portions each having a thickness of less than 8 nm (for example, 5 nm or less). Here, as described above, the ferroelectric film tends to exhibit ferroelectricity when the thickness is 8 nm or more, and tends not to exhibit ferroelectricity when the thickness is less than 8 nm. In particular, when the thickness of the ferroelectric film is 5 nm or less, the ferroelectric film tends not to exhibit ferroelectricity. Therefore, with such a configuration, it is possible to divide the region exhibiting ferroelectricity in the Z direction for each memory cell MC. Accordingly, it is possible to reduce polarization reversal in the portion of the ferroelectric film 632 provided at a height position corresponding to the insulating layer 101.

### [Manufacturing Method]

Next, with reference to FIGS. 35 to 39, a manufacturing method of the semiconductor memory device according to the sixth embodiment will be described. FIGS. 35 to 39 are schematic cross-sectional views illustrating the manufacturing method.

When manufacturing the memory device according to the sixth embodiment, for example, among the manufacturing steps of the semiconductor memory device according to the third embodiment, the steps up to the steps described with reference to FIG. 19 are executed.

Next, as shown in FIG. 35, for example, the insulating film 334 and the region 634 of the ferroelectric film 632 are formed on the inner peripheral surface of the memory hole MH. The step is performed by a method such as CVD or ALD.

Next, as shown in FIG. 36, for example, an insulating member 631A is formed on the inner peripheral surface of the memory hole MH. The step is performed by a method such as CVD.

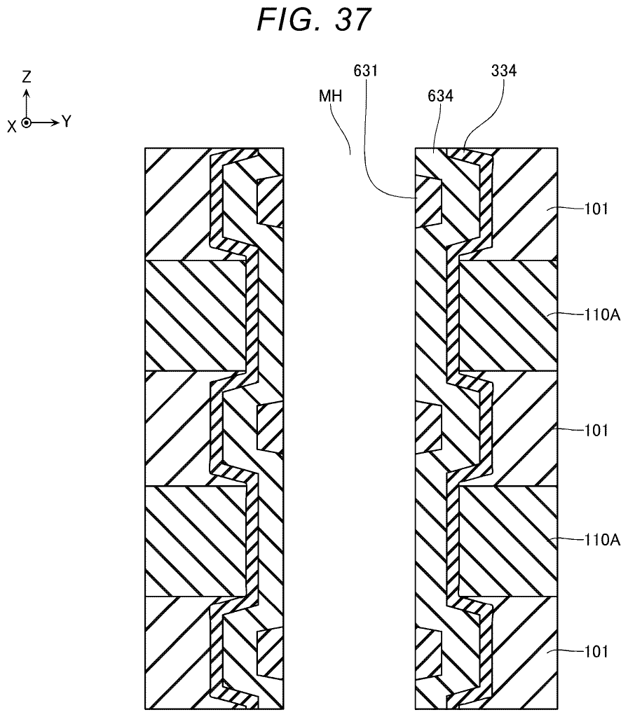

Next, as shown in FIG. 37, for example, a part of the insulating member 631A is removed. Here, a portion of region 634 provided at a height position corresponding to sacrificial layer 110A is exposed inside the memory hole MH. The insulating member 631A is divided into a plurality of insulating members 631 arranged in the Z direction. The step is performed by a method such as wet etching.

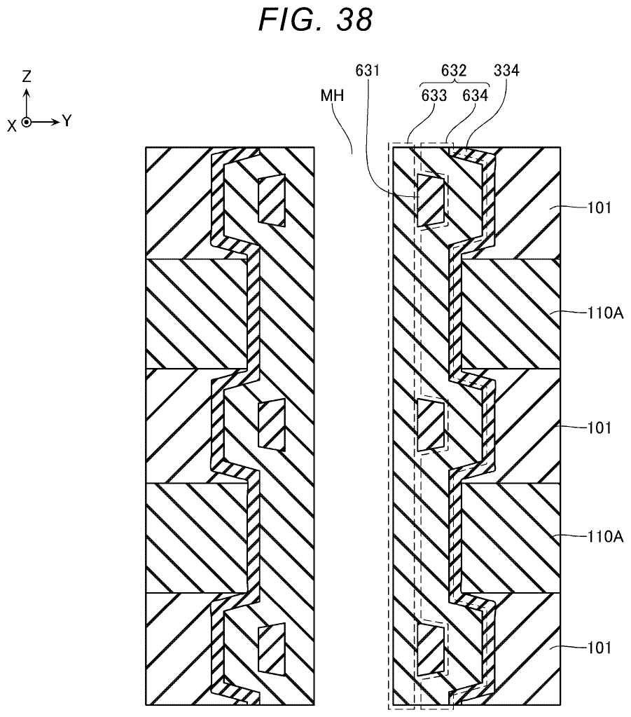

Next, as shown in FIG. 38, for example, the region 633 of the ferroelectric film 632 is formed inside the memory hole MH. The step is performed by a method such as CVD.

Next, as shown in FIG. 39, for example, the insulating film 132 and the semiconductor layer 120 are formed inside the memory hole MH. The step is performed by a method such as CVD.

Thereafter, a structure as described with reference to FIG. 34 is manufactured by forming a groove by RIE or the like at a position corresponding to the electrode 140 described with reference to FIG. 3, removing the sacrificial layer 110A by wet etching or the like through the groove, and forming the conductive layer 110 by means such as CVD.

### Seventh Embodiment

As described with reference to FIG. 34, in the sixth embodiment, the regions 633 and 634 of the ferroelectric film 632 are connected to each other at a plurality of height positions corresponding to the plurality of conductive layers 110. However, such a configuration is merely an example, and the specific configuration can be adjusted as appropriate. For example, the regions 633 and 634 may be spaced apart from each other. Hereinafter, such a configuration will be illustrated as a semiconductor memory device according to a seventh embodiment.

### [Configuration]

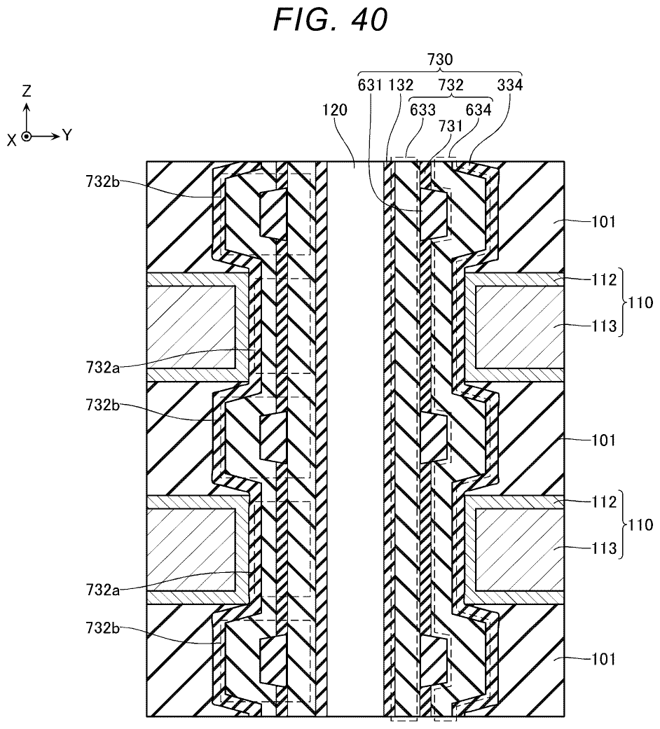

FIG. 40 is a schematic cross-sectional view showing a partial configuration of the semiconductor memory device according to the seventh embodiment.

The semiconductor memory device according to the seventh embodiment is basically configured similarly to the semiconductor memory device according to the sixth embodiment. However, the semiconductor memory device according to the seventh embodiment includes a gate insulating film 730 instead of the gate insulating film 630. The gate insulating film 730 is basically configured similarly to the gate insulating film 630. However, the gate insulating film 630 includes a ferroelectric film 732 instead of the ferroelectric film 632.

The ferroelectric film 732 is basically configured similarly to the ferroelectric film 632. However, an outer diameter of a portion 732b of the ferroelectric film 732 provided at a height corresponding to the insulating layer 101 is larger than an outer diameter of a portion 732a provided at a height corresponding to the conductive layer 110.

That is, the ferroelectric film 732 includes a plurality of portions 732a provided at a plurality of height positions corresponding to the plurality of conductive layers 110, and a plurality of portions 732b provided at a plurality of height positions corresponding to the plurality of insulating layers 101. The inner diameters of the plurality of portions 732b substantially match the inner diameters of the plurality of portions 732a. The outer diameters of the plurality of portions 732b are larger than the outer diameters of the plurality of portions 732a.

The portion 732a mainly includes orthorhombic crystals and exhibits ferroelectricity. On the other hand, the portion 732b mainly includes a crystal structure other than orthorhombic crystals, and does not exhibit ferroelectricity.

The ferroelectric film 732 includes a plurality of additive regions 731 arranged in the Z direction corresponding to the plurality of conductive layers 110 and provided between the regions 633 and 634.

The additive region 731 includes at least one additive element selected from a group including titanium (Ti) and silicon (Si), in addition to the first additive element described above. Hereinafter, such an additive element may be referred to as a “fourth additive element”.

In the present embodiment, the regions 633 and 634 may or may not include the fourth additive element, in addition to the first additive element described above. When the regions 633 and 634 include the fourth additive element, the concentration of the fourth additive element in the regions 633 and 634 is lower than the concentration of the fourth additive element in the additive region 731. When the regions 633 and 634 include the fourth additive element, a boundary between the regions 633 and 634 and the additive region 731 may be, for example, a position where the concentration of the fourth additive element is half of a peak value. When the regions 633 and 634 do not include the fourth additive element, a boundary between the regions 633 and 634 and the additive region 731 may be, for example, a boundary between a region including the fourth additive element and a region not including the fourth additive element, or may be a boundary between a region where the fourth additive element can be detected and a region where the fourth additive element cannot be detected.

Even in the seventh embodiment, a distance from the inner peripheral surface (the surface on the semiconductor layer 120 side) of the plurality of portions of the region 634 corresponding to the plurality of insulating layers 101 to the region 633 is larger than a distance from the inner peripheral surface (the surface on the semiconductor layer 120 side) of the plurality of portions corresponding to the plurality of conductive layers 110 to the region 633. However, the plurality of portions corresponding to the plurality of conductive layers 110 are spaced apart from the region 633 via the additive region 731. Therefore, the distance from the inner peripheral surfaces of the plurality of portions corresponding to the plurality of conductive layers 110 to the region 633 is not zero.

### [Wake-Up Operation]

In the seventh embodiment, the region 633 and the region 634 of the ferroelectric film 732 are divided in a radial direction of the semiconductor layer 120 via the additive region 731. Here, for example, when the thickness of the regions 633 and 634 is less than 8 nm, the ferroelectric film 732 tends not to exhibit ferroelectricity. Then, for example, it is conceivable to perform a wake-up operation before shipping the semiconductor memory device.

The wake-up operation is an operation of alternately supplying a positive polarity voltage and a negative polarity voltage plurality of times between the semiconductor layer 120 and the conductive layer 110, thereby causing the ferroelectric film 732 to exhibit ferroelectricity. Here, absolute values of the positive polarity voltage and the negative polarity voltage supplied between the semiconductor layer 120 and the conductive layer 110 are greater than absolute values of the write voltage VPGM and the erase voltage Vera, respectively, which are explained with reference to FIG. 6.

When the wake-up operation is performed, an electric field is applied to the portion 732a of the ferroelectric film 732, and the characteristics of the portion 732a change. After the wake-up operation is executed, the portion 732a of the ferroelectric film 732 mainly includes orthorhombic crystals and exhibits ferroelectricity. For example, after the wake-up operation is performed, in the portion 732a, the region where the angle difference between the polarization axis direction and the electric field direction (radial direction of the semiconductor layer 120) is 45 degrees or less occupies 75% or more of the entire region.

Here, the gate insulating film 730 according to the seventh embodiment includes a plurality of insulating members 631 arranged in the Z direction, similarly to the gate insulating film 630 according to the sixth embodiment. Therefore, even during the wake-up operation, the lines of electric force from the conductive layer 110 avoid the insulating layer 101 and reach the semiconductor layer 120. Therefore, no electric field is applied to the portion 732b of the ferroelectric film 732, and the characteristics of the portion 732b do not change. Therefore, even after the wake-up operation is executed, the portion 732b mainly includes a crystal structure other than orthorhombic crystals, and does not exhibit ferroelectricity.

### [Effect]

Even in the semiconductor memory device according to the seventh embodiment, similar to the semiconductor memory device according to the sixth embodiment, it is possible to reduce polarization reversal in the portion of the ferroelectric film 732 provided at a height position corresponding to the insulating layer 101 or the adjacent word line WL.

In the semiconductor memory device according to the seventh embodiment, the crystal structure of the portion 732a of the ferroelectric film 732 is modified by the wake-up operation, thereby exhibiting ferroelectricity. In a structure formed by such a method, the characteristics are unlikely to deteriorate even if write operations and erase operations are repeatedly performed. Therefore, according to the semiconductor memory device according to the seventh embodiment, it is possible to extend a lifetime of the semiconductor memory device.

### [Manufacturing Method]

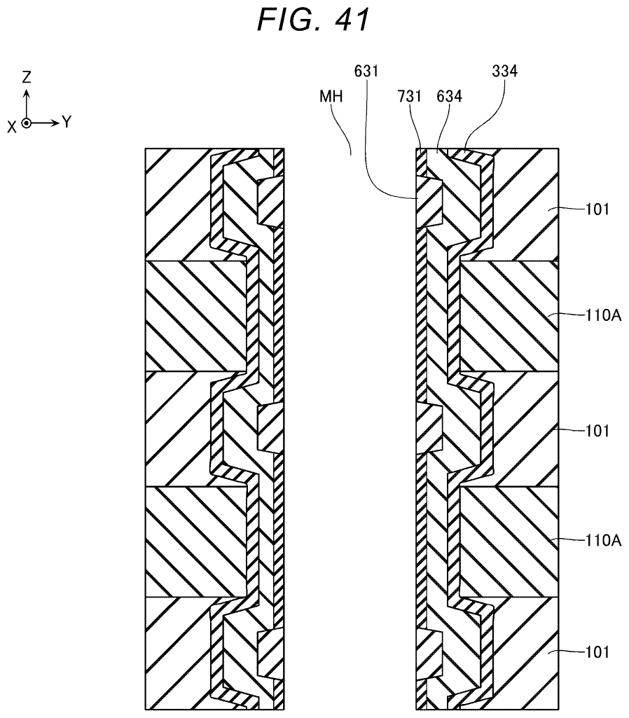

Next, with reference to FIGS. 41 to 43, a manufacturing method of the semiconductor memory device according to the seventh embodiment will be described. FIGS. 41 to 43 are schematic cross-sectional views illustrating the manufacturing method.

When manufacturing the semiconductor memory device according to the seventh embodiment, for example, among the manufacturing steps of the semiconductor memory device according to the sixth embodiment, the steps up to the steps described with reference to FIG. 37 are executed.

Next, as shown in FIG. 41, for example, the fourth additive element is added to the region 634 of the ferroelectric film 732 via the memory hole MH. Thus, the additive region 731 of the ferroelectric film 732 is formed.

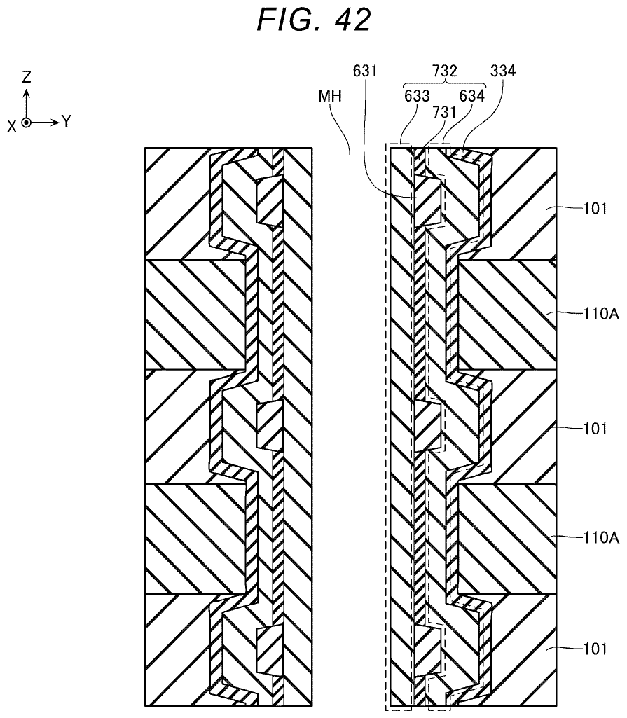

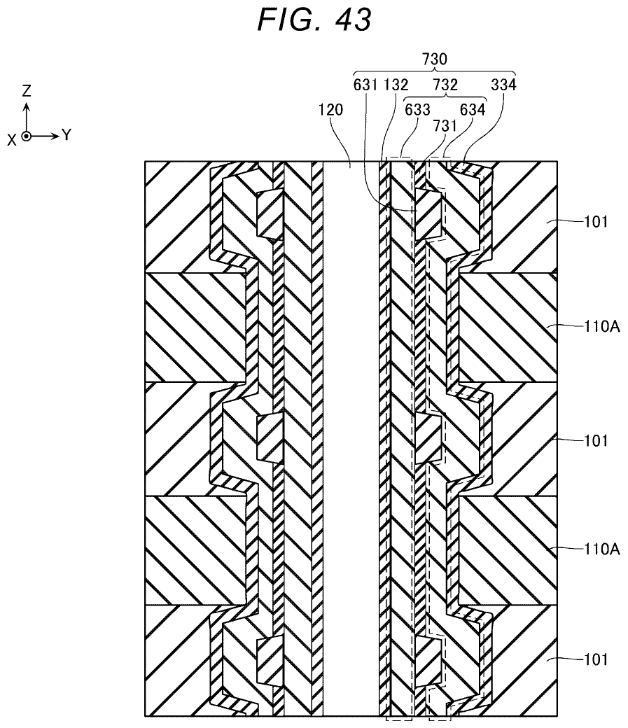

Next, as shown in FIG. 42, for example, the region 633 of the ferroelectric film 732 is formed inside the memory hole MH. The step is performed by a method such as CVD or ALD.

Next, as shown in FIG. 43, for example, the insulating film 132 and the semiconductor layer 120 are formed inside the memory hole MH. The step is performed by a method such as CVD.

Thereafter, a structure as described with reference to FIG. 40 is manufactured by forming a groove by RIE or the like at a position corresponding to the electrode 140 described with reference to FIG. 3, removing the sacrificial layer 110A by wet etching or the like through the groove, and forming the conductive layer 110 by means such as CVD.

### Other Embodiments

The semiconductor memory devices according to the first to seventh embodiments have been described above. However, the above description is merely an example, and the specific configuration or the like can be adjusted as appropriate.

For example, in the first to seventh embodiments, the semiconductor layer 120 having a configuration of a substantially columnar shape has been described. However, the semiconductor layer 120 may have a configuration of a substantially cylindrical shape, for example. The central portion of the semiconductor layer 120 may be filled with an insulating film of silicon oxide (SiO₂) or the like.

For example, in the outer peripheral surfaces of the ferroelectric film 332 (FIG. 18), the ferroelectric film 432 (FIG. 24), the ferroelectric film 632 (FIG. 34), and the ferroelectric film 732 (FIG. 40) or in vicinities thereof, an additive region including the second additive element (a region corresponding to the additive region 135 in FIG. 4) may be provided as in the first embodiment, or a region not including the second additive element (region corresponding to region 235 in FIG. 16) and an additive region including the second additive element provided on the inner peripheral side (the region corresponding to additive region 236 in FIG. 16) may be provided as in the second embodiment.

According to such a configuration, similarly to the semiconductor memory device according to the first embodiment and the semiconductor memory device according to the second embodiment, it is possible to reduce the occurrence of erroneous writing associated with execution of the read operation.

The gate insulating film 630 (FIG. 34) and the gate insulating film 730 (FIG. 40) may include a plurality of insulating members 331 and an insulating film 333 instead of the insulating film 132.

According to such a configuration, similarly to the semiconductor memory device according to the third embodiment and the semiconductor memory device according to the fourth embodiment, it is possible to reduce the deterioration of the threshold voltage characteristics due to an increase in the number of write/erase operations. It is possible to reduce a decrease in the current flowing through the semiconductor layer 120.

As described above, the portion of the ferroelectric film 632 (FIG. 34) provided at a height position corresponding to the insulating layer 101 is divided into two portions having a relatively small thickness via the insulating member 631. Here, the portion of the ferroelectric film 632 (FIG. 34) provided at a height position corresponding to the insulating layer 101 may be divided into three or more portions.

To manufacture such a configuration, for example, in the step described with reference to FIG. 37, a large amount of the insulating member 631A is removed to form a step between the insulating member 631 and a part (region 634) of the ferroelectric film 632. In the step described with reference to FIG. 38, a part of the ferroelectric film 632 is formed to be thin enough to maintain the above-described step difference. Next, the insulating member 631A (FIG. 36) is formed again inside the memory hole MH. Thereafter, similar steps are repeated.

### OTHERS

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a semiconductor layer;
a gate electrode facing the semiconductor layer;
a first insulating film provided between the semiconductor layer and the gate electrode, and including at least one of oxygen (O), hafnium (Hf), or a first additive element, the first insulating film formed with an orthorhombic crystal structure; and
a second insulating film provided between the first insulating film and the gate electrode, wherein
the first insulating film includes
a first additive region,
a second additive region provided between the first additive region and the gate electrode, and
a memory region provided between the first additive region and the second additive region,
the first additive region includes a second additive element selected from a group consisting of ruthenium (Ru), titanium (Ti), molybdenum (Mo), tantalum (Ta), tungsten (W), platinum (Pt), and combinations thereof,
the second additive region includes a third additive element selected from a group consisting of ruthenium (Ru), titanium (Ti), molybdenum (Mo), tantalum (Ta), tungsten (W), platinum (Pt), and combinations thereof,
the memory region does not include the second additive element, or a concentration of the second additive element in the memory region is lower than a concentration of the second additive element in the first additive region, and
the memory region does not include the third additive element, or a concentration of the third additive element in the memory region is lower than a concentration of the third additive element in the second additive region.

2. The semiconductor memory device according to claim 1, wherein
the first insulating film includes the first additive element selected from a group consisting of silicon (Si), zirconium (Zr), aluminum (Al), yttrium (Y), strontium (Sr), lanthanum (La), samarium (Sm), gadolinium (Gd), terbium (Tb), dysprosium (Dy), holmium (Ho), erbium (Er), ytterbium (Yb), lutetium (Lu), barium (Ba), and combinations thereof.

3. The semiconductor memory device according to claim 1, wherein
the first additive region includes a surface of the first insulating film on a side of the semiconductor layer, and
the second additive region includes a surface of the first insulating film on a side of the gate electrode.

4. The semiconductor memory device according to claim 1, wherein
the first insulating film includes a region provided between the second additive region and the gate electrode,
the first additive region includes a surface of the first insulating film on a side of the semiconductor layer, and
the region includes a surface of the first insulating film on a side of the gate electrode.

5. The semiconductor memory device according to claim 1, wherein
a concentration of the second additive element in the first additive region is equal to or less than 6.2×10²¹ pieces/cm³, and
a concentration of the third additive element in the second additive region is equal to or less than 6.2×10²¹ pieces/cm³.

6. The semiconductor memory device according to claim 1, wherein
a distance between the first additive region and the second additive region is equal to or greater than 8 nm.

7. A semiconductor memory device comprising:
a plurality of conductive layers and a plurality of insulating layers alternately stacked in a stacking direction;
a semiconductor layer extending in the stacking direction and facing the plurality of conductive layers;
an insulating film provided between the plurality of conductive layers and the semiconductor layer, extending in the stacking direction, and including at least one of oxygen (O) or hafnium (Hf), the insulating film formed with an orthorhombic crystal structure; and
a boundary layer provided between the insulating film and the semiconductor layer and extending in the stacking direction, wherein
the boundary layer includes
a plurality f first portions provided at a plurality of positions corresponding to the plurality of conductive layers in the stacking direction, respectively, and
a plurality of second portions provided at a plurality of positions corresponding to the plurality of insulating layers in the stacking direction, respectively, and
a distance from the plurality of second portions to the semiconductor layer is greater than a distance from the plurality of first portions to the semiconductor layer.

8. The semiconductor memory device according to claim 7, wherein
a difference between the distance from the plurality of second portions to the semiconductor layer and the distance from the plurality of first portions to the semiconductor layer is equal to or greater than 2 nm.

9. The semiconductor memory device according to claim 7, wherein
the insulating film includes
a plurality of third portions provided at a plurality of positions corresponding to the plurality of conductive layers in the stacking direction, respectively, and
a plurality of fourth portions provided at a plurality of positions corresponding to the plurality of insulating layers in the stacking direction, respectively, and
a distance from the plurality of fourth portions to the semiconductor layer is greater than a distance from the plurality of third portions to the semiconductor layer.

10. The semiconductor memory device according to claim 7, further comprising:
a plurality of insulating members arranged along a surface of the semiconductor layer on a side of the plurality of conductive layers and in the stacking direction corresponding to the plurality of insulating layers, respectively, wherein
the boundary layer extends in the stacking direction along surfaces of the semiconductor layer and the plurality of insulating members on the side of the plurality of conductive layers, and
the insulating film extends in the stacking direction along a surface of the boundary layer on the side of the plurality of conductive layers.

11. The semiconductor memory device according to claim 7, wherein
the insulating film includes an additive region, and
the additive region includes an additive element selected from a group consisting of ruthenium (Ru), titanium (Ti), molybdenum (Mo), tantalum (Ta), tungsten (W), platinum (Pt), and combinations thereof.

12. The semiconductor memory device according to claim 11, wherein
the additive region extends in the stacking direction over a range in the stacking direction corresponding to the plurality of conductive layers.

13. The semiconductor memory device according to claim 11, further comprising:
a plurality of the additive regions provided at a plurality of positions corresponding to the plurality of conductive layers in the stacking direction, respectively.

14. The semiconductor memory device according to claim 7, wherein
the insulating film includes
a plurality of portions provided at a plurality of positions corresponding to the plurality of conductive layers in the stacking direction, respectively, and including a structure that are orthorhombic as a crystal structure, and
a plurality of other portions provided at a plurality of positions corresponding to the plurality of insulating layers in the stacking direction, respectively, and including a structure that are not orthorhombic as a crystal structure.

15. A semiconductor memory device comprising:
a plurality of conductive layers and a plurality of insulating layers alternately stacked in a stacking direction;
a semiconductor layer extending in the stacking direction and facing the plurality of conductive layers; and
an insulating film provided between the plurality of conductive layers and the semiconductor layer, extending in the stacking direction, and including at least one of oxygen (O) or hafnium (Hf), the insulating film formed with an orthorhombic crystal structure, wherein
the insulating film includes
a first region extending in the stacking direction along a surface of the semiconductor layer on a side of the plurality of conductive layers, and
a second region provided between the first region and the plurality of conductive layers and extending in the stacking direction,
the first region and the second region are separated from each other, at a plurality of first positions corresponding to the plurality of insulating layers in the stacking direction, respectively, and
the first region and the second region are connected at a plurality of second positions corresponding to the plurality of conductive layers in the stacking direction, respectively, or a distance between the first region and the second region at the plurality of second positions is smaller than a distance between the first region and the second region at the plurality of first positions.

16. The semiconductor memory device according to claim 15, further comprising:
a plurality of insulating members arranged along a surface of the first region on the side of the plurality of conductive layers and in the stacking direction corresponding to the plurality of insulating layers, respectively, wherein
the second region extends in the stacking direction along surfaces of the first region and the plurality of insulating members on the side of the plurality of conductive layers.

17. The semiconductor memory device according to claim 16, wherein
a first distance between the plurality of insulating members and a surface of the insulating film on a side of the semiconductor layer is equal to or less than 5 nm, and
a second distance between the plurality of insulating members and a surface of the insulating film on the side of the plurality of conductive layers is equal to or less than 5 nm.

18. The semiconductor memory device according to claim 17, wherein
a sum of the first distance and the second distance is equal to or greater than 8 nm.

19. The semiconductor memory device according to claim 16, wherein
a distance between the surface of the plurality of insulating members on a side of the semiconductor layer and the surface of the plurality of insulating members on the side of the plurality of conductive layers is equal to or greater than 1 nm.

20. The semiconductor memory device according to claim 15, wherein
the insulating film includes a plurality of additive regions arranged in the stacking direction corresponding to the plurality of conductive layers between the first region and the second region, respectively,
the additive region includes additive element selected from a group consisting of titanium (Ti), silicon (Si), and combinations thereof, and
the first region and the second region do not include the additive element, or the concentration of the additive element in the first region and the second region is lower than the concentration of the additive element in the additive region.
